(19) United States
(12) Patent Application Publication
(10) Pub. No.: US 2003/0022412 A1
(43) Pub. Date: Jan. 30, 2003

(54) Monolithic semiconductor-piezoelectric device structures and electroacoustic charge transport devices

(75) Inventors: Robert J. Higgins, Plantation, FL (US); Kenneth D. Cornett, Coral Springs, FL (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/911,496

(22) Filed: Jul. 25, 2001

(51) Int. Cl. H01L 21/00

(52) U.S. Cl. 438/50

(57) ABSTRACT

An epitaxial layer of crystalline piezoelectric material such as lithium niobate and lithium tantalate can be grown overlying a silicon wafer by first growing an intermediate strain-relief layer on the silicon wafer. Early in the growth of the piezoelectric layer, the strain-relief layer is a crystalline metal oxide, which helps bridge the lattice mismatch between silicon and the piezoelectric material. After growth of a thin crystalline piezoelectric layer, the strain-relief layer is amorphized to decouple the silicon and piezoelectric crystal lattices. Growth of the piezoelectric layer may then be resumed to obtain a good quality thicker layer suitable for electro-acoustic device fabrication. Passive and active electro-acoustic devices may be fabricated using the epitaxial piezoelectric layer. In particular, acoustic charge transport devices that utilize device elements in both silicon and the piezoelectric epitaxial overlayer are designed and fabricated. The electro-acoustic devices may be integrated with semiconductor device circuitry fabricated on the silicon wafer.

### FIELD OF THE INVENTION

This invention relates generally to monolithic semiconductor device structures, and more particularly to monolithic semiconductor device structures which include individual devices formed with different types of material. Even more particularly, this invention relates to monolithic semiconductor device structures which also include piezoelectric material that may be used to form electro-acoustic devices.

### BACKGROUND OF THE INVENTION

Worldwide, over 90% solid state electronic devices and integrated circuits are fabricated using silicon as the raw material. This pre-eminence of silicon as the raw material of choice is in large part due to the favorable economics of device and integrated circuit manufacturing using silicon. High quality monocrystalline silicon substrate wafers are readily available at reasonable cost and at progressively higher wafer diameters suitable for large volume manufacturing.

However, silicon does not have physical properties suitable for all types of solid state devices. Some devices in their operation exploit physical properties of some materials that are unique or that are superior to those of silicon. These devices must be made using materials other than silicon despite the relatively unfavorable economics of such use. For example, silicon has an indirect band gap unsuitable for opto-electronic device operation. Therefore, conventional opto-electronic devices are made from direct band gap semiconductors such as III-V compound semiconductors instead of silicon.

Further, for some specialized electronic devices such as electro-acoustic devices, use of material other than elemental or compound semiconductors may be preferable. For example, the performance characteristics of electro-acoustic devices such as surface acoustic wave (SAW) devices depends on the piezoelectric properties of the material from which they are made. Silicon itself is non-piezoelectric. Some compound semiconductors, for example, gallium arsenide, do exhibit piezoelectricity, but their piezoelectric characteristics are weak compared to, for example, material such as crystalline lithium niobate or lithium tantalate. These latter materials and others such as quartz, lithium tetraborate, and bismuth germanium oxide in suitable crystalline form are commercially used for making discrete surface acoustic wave (SAW) devices. These SAW devices are designed for use, for example, as pulse compression filters, bandpass filters, delay lines, resonators, oscillators, convolvers, and matched filters for spread spectrum.

The use of SAW devices in a signal processing circuitry is now ubiquitous. SAW devices find applications in signal processing circuits ranging from radar and communication systems to consumer electronics including receivers, pagers and cellular phones. The general technological trends toward increased miniaturization of electronics as seen, for example, in consumer electronics, also have led to smaller and smaller SAW device modules. Smaller SAW devices have been achieved in part by the use of resonant and semi-resonant designs and new substrate materials. However, even further desirable miniaturization of signal processing circuitry may be possible, if present day hybrid SAW components could be monolithically integrated with the semiconductor integrated circuit components in the signal processing circuitry.

Thus, there is a need for incorporating piezoelectric material suitable for making electro-acoustic devices in monolithic structures used for making semiconductor integrated circuits.

However, the desirable piezoelectric and other physical properties of most material suitable for making devices are a function of crystalline quality of the materials. Therefore, both the piezoelectric material and the semiconductor material (e.g., silicon) in the monolithic structure must be formed together without degrading the crystalline quality of either material, if the monolithic structure is to be useful for integrating devices made in the disparate materials.

Growing or depositing good quality piezoelectric material on silicon substrates is non-trivial because of the different crystalline structure of the two materials. The invariably different crystal lattice dimensions of the two materials cause stresses and strains in at least one of the materials sufficient to degrade its crystalline quality and, therefore, its physical properties that are essential for device operation.

The challenges in forming good crystalline quality heterogeneous material structures are not unique to the combination of piezoelectric materials and silicon. In widespread conventional attempts to integrate different types of semiconductor devices, other combinations of device materials have been or are being sought. The combinations commonly sought include combinations of different types of semiconductors such as Group IV elemental semiconductors (e.g., silicon) with Group III-V or Group II-VI compound semiconductors, (e.g., gallium arsenide (GaAs), and indium phosphide (InP)). These widespread attempts to form composite structures of disparate semiconductors with silicon are driven by the desire to maximize benefits from both materials. For example, attempts at forming GaAs-based compound semiconductor thin films on silicon substrates, seek to benefit from the ruggedness of silicon and its amenability to device and integrated circuit manufacturing on a large scale, and from the special electronic properties of compound semiconductors that make them useful, for example, for high-speed devices and for opto-electronic devices such as lasers.

Compound semiconductors are a different class of materials than the commonly used piezoelectric materials mentioned above. Yet, it may be useful to approach the challenges of forming good quality piezoelectric-silicon monolithic structures within the context of the broader problem of the heterogeneous growth of any disparate material including compound semiconductors on elemental semiconductor substrates.

### BRIEF DESCRIPTION OF THE DRAWINGS

The above and other objects and advantages of the invention will be apparent upon consideration of the following detailed description, taken in conjunction with the accompanying drawings, in which like reference characters refer to like parts throughout, and in which:

FIGS. 1-3 illustrate schematically, in cross-section, composite semiconductor device structures that can be used in accordance with various embodiments of the invention;

FIG. 4 illustrates graphically the relationship between maximum attainable film thickness and lattice mismatch between a host crystal and a grown crystalline overlayer;

FIG. 5 is a high resolution Transmission Electron Micrograph (TEM) of illustrative semiconductor material manufactured in accordance with what is shown herein;

FIG. 6 is an X-ray diffraction taken on an illustrative semiconductor structure manufactured in accordance with what is shown herein;

FIG. 7 illustrates a high resolution TEM of a structure including an amorphous oxide layer;

FIG. 8 illustrates an X-ray diffraction spectrum of a structure including an amorphous oxide layer;

FIGS. 9-12 illustrate schematically, in cross-section, the formation of a composite device structure in accordance with another embodiment of the invention;

FIGS. 13-16 illustrate a probable molecular bonding structure of the device structures illustrated in FIGS. 9-12;

FIGS. 17-20 illustrate schematically in cross-section the formation of a composite device structure in accordance with still another embodiment of the invention;

FIGS. 21-23 illustrate schematically in cross-section the formation of a yet another embodiment of a composite device structure in accordance with the invention;

FIGS. 24 and 25 illustrate schematically in cross-section composite device structures that can be used in accordance with various embodiments of the invention;

FIGS. 26-30 include illustrations of cross-sectional views of a portion of an integrated circuit that includes a compound semiconductor portion, a bipolar portion, and a MOS portion in accordance with what is shown herein;

FIGS. 31-33 illustrate schematically in cross-section the formation of monolithic structures that include piezoelectric materials in accordance with various embodiments of the invention;

FIGS. 34 and 36 illustrate schematically in cross-section monolithic structures that can be used in accordance with various embodiments of the invention;

FIG. 35 illustrates schematically in plan view a SAW convolver formed in the monolithic structure of FIG. 34 in accordance with an embodiment of the invention;

FIG. 37 illustrates schematically in cross-section the formation of a monolithic structure that includes piezoelectric material suitable for fabrication of electro-acoustic devices in accordance with an embodiment of the invention; and

FIGS. 38 and 39 illustrate schematically in cross-section embodiments of acoustic charge transport devices in accordance with the invention.

Skilled artisans will appreciate that in many cases elements in certain FIGS. are illustrated for simplicity and clarity and have not necessarily been drawn to scale. For example, the dimensions of some of the elements in certain FIGS. may be exaggerated relative to other elements to help to improve understanding of what is being shown.

### DETAILED DESCRIPTION OF THE INVENTION

The difficulty in formation of heterogeneous structures of disparate crystalline materials having different lattice spacing is at least to the first approximation a problem of mechanical stability. Crystal surfaces have a natural tendency or preference to maintain their crystalline habit, that is, to grow maintaining the lattice spacing and the crystallographic arrangement of atoms or molecules in the bulk crystal. Growing a film of a first crystal directly on a second crystal having a different lattice spacing than the first, causes the lattice spacing of atoms or molecules in both the crystals near the growth interface to mutually adjust toward a common value. This mutual stretching or compression of the lattice spacings causes mechanical stress and/or strains in both crystals. The natural elasticity of the crystals may allow some stretching or compression of the lattice spacing, but as the second crystal film or layer grows thicker, the continued mechanical distortion of its lattice spacing causes its crystalline structure to degrade. This phenomenon is commonly understood and described in terms of the elastic properties of the crystals. The crystalline structure of the growing layer (in colloquial terms) begins to fall apart when the mechanical stresses or strains in it due to lattice mismatch exceed the elastic limits of the crystal or the strength of the electronic bonds at the interface between the two materials.

In the growth of heterogeneous material films on a substrate, the details of the exact nature of atoms or molecules in the two materials are thought to play a secondary role in the mechanical lattice-mismatch/elasticity phenomena. With this perspective, it seems reasonable to consider the problem of forming piezoelectric-semiconductor monolithic structures as a general problem of lattice-spacing mismatch in the context of forming heterogeneous structures of disparate material including different types of semiconductor materials as well as piezoelectric materials.

The present disclosure addresses the formation of semiconductor-semiconductor structures and piezoelectric-semiconductor structures of different types.

For convenience herein, the semiconductor-semiconductor structures are sometimes referred to as “composite semiconductor structures” or “composite integrated circuits” because they include two (or more) significantly different types of semiconductor devices in one integrated structure or circuit. For example, one of these two types of devices may be silicon-based devices such as CMOS devices, and the other of these two types of devices may be compound semiconductor devices such GaAs devices. Illustrative composite semiconductor structures and methods for making such structures are disclosed in Ramdani et al. U.S. patent application Ser. No. 09/502,023, filed Feb. 10, 2000, which is hereby incorporated by reference herein in its entirety. Certain material from that reference is substantially repeated below to ensure that there is support herein for references to composite semiconductor structures and composite integrated circuits.

Similarly, for convenience piezoelectric-semiconductor structures that include piezoelectric material in addition to one or more semiconductors are referred to herein as monolithic structures.

FIG. 1 illustrates schematically in cross-section a portion of a semiconductor structure 20 which may be relevant to or useful in connection with certain embodiments of the present invention. Semiconductor structure 20 includes a monocrystalline substrate 22, accommodating buffer layer 24 comprising a monocrystalline material, and a layer 26 of a monocrystalline compound semiconductor material. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment, structure 20 also includes an amorphous intermediate layer 28 positioned between substrate 22 and accommodating buffer layer 24. Structure 20 may also include a template layer 30 between accommodating buffer layer 24 and compound semiconductor layer 26. As will be explained more fully below, template layer 30 helps to initiate the growth of compound semiconductor layer 26 on accommodating buffer layer 24. Amorphous intermediate layer 28 helps to relieve the strain in accommodating buffer layer 24 and by doing so, aids in the growth of a high crystalline quality accommodating buffer layer 24.

Substrate 22, in accordance with one embodiment, is a monocrystalline semiconductor wafer, preferably of large diameter. The wafer can be of a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate 22. In accordance with one embodiment, amorphous intermediate layer 28 is grown on substrate 22 at the interface between substrate 22 and the growing accommodating buffer layer 24 by the oxidation of substrate 22 during the growth of layer 24. Amorphous intermediate layer 28 serves to relieve strain that might otherwise occur in monocrystalline accommodating buffer layer 24 as a result of differences in the lattice constants of substrate 22 and buffer layer 24. As used herein, lattice constant refers to the distance between atoms of a cell measured in the plane of the surface. If such strain is not relieved by amorphous intermediate layer 28, the strain may cause defects in the crystalline structure of accommodating buffer layer 24. Defects in the crystalline structure of accommodating buffer layer 24, in turn, would make it difficult to achieve a high quality crystalline structure in monocrystalline compound semiconductor layer 26.

Accommodating buffer layer 24 is preferably a monocrystalline oxide or nitride material selected for its crystalline compatibility with underlying substrate 22 and with overlying compound semiconductor material 26. For example, the material could be an oxide or nitride having a lattice structure matched to substrate 22 and to the subsequently applied semiconductor material 26. Materials that are suitable for accommodating buffer layer 24 include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for accommodating buffer layer 24. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Several of these oxides and nitrides (e.g., strontium barium titanate and aluminum nitride) that may be used for accommodating buffer layer 24 also have piezoelectric properties that make them suitable for use in electro-acoustic devices.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5.0 nm.

The compound semiconductor material of layer 26 can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. Suitable template 30 materials chemically bond to the surface of the accommodating buffer layer 24 at selected sites and provide sites for the nucleation of the epitaxial growth of the subsequent compound semiconductor layer 26. Appropriate materials for template 30 are discussed below.

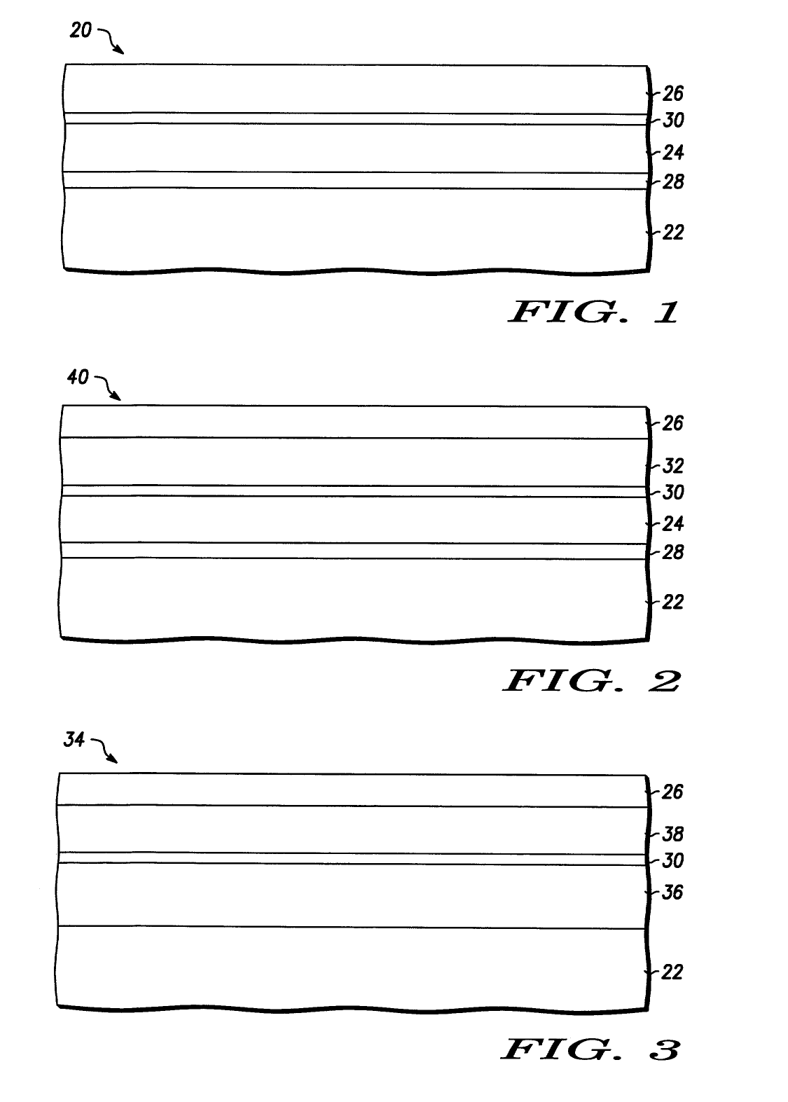

FIG. 2 illustrates in cross-section a portion of a semiconductor structure 40 in accordance with a further embodiment. Structure 40 is similar to the previously described semiconductor structure 20 except that an additional buffer layer 32 is positioned between accommodating buffer layer 24 and layer of monocrystalline compound semiconductor material 26. Specifically, additional buffer layer 32 is positioned between the template layer 30 and the overlying layer 26 of compound semiconductor material. Additional buffer layer 32, formed of a semiconductor or compound semiconductor material, serves to provide a lattice compensation when the lattice constant of accommodating buffer layer 24 cannot be adequately matched to the overlying monocrystalline compound semiconductor material layer 26.

FIG. 3 schematically illustrates in cross-section a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional semiconductor layer 38.

As explained in greater detail below, amorphous layer 36 may be formed by first forming an accommodating buffer layer and an amorphous interface layer in a similar manner to that described above. Monocrystalline semiconductor layer 26 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and semiconductor layer 38 (subsequent to layer 38 formation) relieves stresses between layers 22 and 38 and provides a true compliant substrate for subsequent processing—e.g., compound semiconductor layer 26 formation.

The processes previously described above in connection with FIGS. 1 and 2 are adequate for growing monocrystalline compound semiconductor layers over a monocrystalline substrate. However, the process described in connection with FIG. 3, which includes transforming a monocrystalline accommodating buffer layer to an amorphous oxide layer, may be better for growing monocrystalline compound semiconductor layers because it allows any strain in layer 26 to relax.

Semiconductor layer 38 may include any of the materials described throughout this application in connection with either of compound semiconductor material layer 26 or additional buffer layer 32. For example, layer 38 may include monocrystalline Group IV or monocrystalline compound semiconductor materials.

In accordance with one embodiment of the present invention, semiconductor layer 38 serves as an anneal cap during layer 36 formation and as a template for subsequent semiconductor layer 26 formation. Accordingly, layer 38 is preferably thick enough to provide a suitable template for layer 26 growth (at least one monolayer) and thin enough to allow layer 38 to form as a substantially defect free monocrystalline semiconductor compound.

In accordance with another embodiment of the invention, semiconductor layer 38 comprises compound semiconductor material (e.g., a material discussed above in connection with compound semiconductor layer 26) that is thick enough to form devices within layer 38. In this case, a semiconductor structure in accordance with the present invention does not include compound semiconductor layer 26. In other words, the semiconductor structure in accordance with this embodiment only includes one compound semiconductor layer disposed above amorphous oxide layer 36.

The layer formed on substrate 22, whether it includes only accommodating buffer layer 24, accommodating buffer layer 24 with amorphous intermediate or interface layer 28, an amorphous layer such as layer 36 formed by annealing layers 24 and 28 as described above in connection with FIG. 3, or template layer 30, may be referred to generically as an “accommodating layer.”

The following non-limiting, illustrative examples illustrate various combinations of materials useful in structures 20, 40, and 34 in accordance with various alternative embodiments. These examples are merely illustrative, and it is not intended that the invention be limited to these illustrative examples.

### EXAMPLE 1

In accordance with one embodiment, monocrystalline substrate 22 is a silicon substrate oriented in the (100) direction. Silicon substrate 22 can be, for example, a silicon substrate as is commonly used in making complementary metal oxide semiconductor (CMOS) integrated circuits having a diameter of about 200-300 mm. In accordance with this embodiment, accommodating buffer layer 24 is a monocrystalline layer of Sr_{z}Ba_{1-z}TiO₃ where z ranges from 0 to 1 and amorphous intermediate layer 28 is a layer of silicon oxide (SiOₓ) formed at the interface between silicon substrate 22 and accommodating buffer layer 24. The value of z is selected to obtain one or more lattice constants closely matched to corresponding lattice constants of the subsequently formed layer 26. Accommodating buffer layer 24 can have a thickness of about 2 to about 100 nanometers (nm) and preferably has a thickness of about 5 nm. In general, an accommodating buffer layer 24 thick enough to isolate monocrystalline material layer 26 from substrate 22 is desired in order to obtain the desired electrical and optical properties. Layers thicker than 100 nm usually provide little additional benefit while increasing cost unnecessarily; however, thicker layers may be fabricated if needed. The amorphous intermediate layer 28 of silicon oxide can have a thickness of about 0.5-5.0 nm, and preferably a thickness of about 1-2 nm.

In accordance with this embodiment, compound semiconductor material layer 26 is a layer of gallium arsenide (GaAs) or aluminum gallium arsenide (AlGaAs) having a thickness of about 1 nm to about 100 micrometers (pm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer 30 is formed by capping the oxide layer. Template layer 30 is preferably 1-10 monolayers of Ti—As, Sr—O—As, Sr—Ga—O, or Sr—Al—O. By way of a preferred example, 1-2 monolayers 30 of Ti—As or Sr—Ga—O have been shown to successfully grow GaAs layers 26.

### EXAMPLE 2

In accordance with a further embodiment, monocrystalline substrate 22 is a silicon substrate as described above. Accommodating buffer layer 24 is a monocrystalline oxide of strontium or barium zirconate or hafnate in a cubic or orthorhombic phase with an amorphous intermediate layer 28 of silicon oxide formed at the interface between silicon substrate 22 and accommodating buffer layer 24. Accommodating buffer layer 24 can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700° C. The lattice structure of the resulting crystalline oxide exhibits a 45° rotation with respect to the substrate 22 silicon lattice structure.

An accommodating buffer layer 24 formed of these zirconate or hafnate materials is suitable for the growth of compound semiconductor materials 26 in the indium phosphide (InP) system. The compound semiconductor material 26 can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template 30 for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O‘As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer 24, the surface is terminated with 1-2 monolayers of zirconium followed by deposition of 1-2 monolayers of arsenic to form a Zr—As template 30. A monocrystalline layer 26 of the compound semiconductor material from the indium phosphide system is then grown on template layer 30. The resulting lattice structure of the compound semiconductor material 26 exhibits a 45 degree rotation with respect to the accommodating buffer layer 24 lattice structure and a lattice mismatch to (100) InP of less than 2.5%, and preferably less than about 1.0%.

### EXAMPLE 3

In accordance with a further embodiment, a structure is provided that is suitable for the growth of an epitaxial film of a II-VI material overlying a silicon substrate 22. The substrate 22 is preferably a silicon wafer as described above. A suitable accommodating buffer layer 24 material is SrₓBa₁₋ₓTiO₃, where x ranges from 0 to 1, having a thickness of about 2-100 nm and preferably a thickness of about 5-15 nm. The II-VI compound semiconductor material 26 can be, for example, zinc selenide (ZnSe) or zinc sulfur selenide (ZnSSe). A suitable template 30 for this material system includes 1-10 monolayers of zinc-oxygen (Zn—O) followed by 1-2 monolayers of an excess of zinc followed by the selenidation of zinc on the surface. Alternatively, a template 30 can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, monocrystalline oxide layer 24, and monocrystalline compound semiconductor material layer 26 can be similar to those described in example 1. In addition, an additional buffer layer 32 serves to alleviate any strains that might result from a mismatch of the crystal lattice of the accommodating buffer layer and the lattice of the monocrystalline semiconductor material. The additional buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1 . In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying compound semiconductor material. The compositions of other materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same as that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline compound semiconductor material layer. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline compound semiconductor material layer 26 and template layer 30 can be the same as those described above in example 2. In addition, a buffer layer 32 is inserted between accommodating buffer layer 24 and overlying monocrystalline compound semiconductor material layer 26. Buffer layer 32, a further monocrystalline semiconductor material, can be, for example, a graded layer of indium gallium arsenide (InGaAs) or indium aluminum arsenide (InAlAs). In accordance with one aspect of this embodiment, buffer layer 32 includes InGaAs, in which the indium composition varies from 0 to about 50%. The additional buffer layer 32 preferably has a thickness of about 10-30 nm. Varying the composition of buffer layer 32 from GaAs to InGaAs serves to provide a lattice match between the underlying monocrystalline oxide material 24 and the overlying layer 26 of monocrystalline compound semiconductor material. Such a buffer layer 32 is especially advantageous if there is a lattice mismatch between accommodating buffer layer 24 and monocrystalline compound semiconductor material layer 26.

### EXAMPLE 6

This example provides exemplary materials useful in structure 34, as illustrated in FIG. 3. Substrate material 22, template layer 30, and monocrystalline compound semiconductor material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of semiconductor material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline compound semiconductor material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of accommodating buffer layer 24 and monocrystalline substrate 22 must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that tend to be polycrystalline. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material 24 by 45° with respect to the crystal orientation of the silicon substrate wafer 22. The inclusion in the structure of amorphous interface layer 28, a silicon oxide layer in this example, if it is of sufficient thickness, serves to reduce strain in the titanate monocrystalline layer 24 that might result from any mismatch in the lattice constants of the host silicon wafer 22 and the grown titanate layer 24. As a result, a high quality, thick, monocrystalline titanate layer 24 is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, accommodating buffer layer 24 must be of high crystalline quality. In addition, in order to achieve high crystalline quality in layer 26, substantial matching between the crystal lattice constant of the host crystal, in this case, monocrystalline accommodating buffer layer 24, and grown crystal 26 is desired. With properly selected materials this substantial matching of lattice constants is achieved as a result of rotation of the crystal orientation of grown crystal 26 with respect to the orientation of host crystal 24. If grown crystal 26 is gallium arsenide, aluminum gallium arsenide, zinc selenide, or zinc sulfur selenide and accommodating buffer layer 24 is monocrystalline SrₓBa₁₋ₓTiO₃, substantial matching of crystal lattice constants of the two materials is achieved, wherein the crystal orientation of grown layer 26 is rotated by 45° with respect to the orientation of the host monocrystalline oxide 24. Similarly, if host material 24 is a strontium or barium zirconate or a strontium or barium hafnate or barium tin oxide and compound semiconductor layer 26 is indium phosphide or gallium indium arsenide or aluminum indium arsenide, substantial matching of crystal lattice constants can be achieved by rotating the orientation of grown crystal layer 26 by 45° with respect to host oxide crystal 24. In some instances, a crystalline semiconductor buffer layer 32 between host oxide 24 and grown compound semiconductor layer 26 can be used to reduce strain in grown monocrystalline compound semiconductor layer 26 that might result from small differences in lattice constants. Better crystalline quality in grown monocrystalline compound semiconductor layer 26 can thereby be achieved.

The following example illustrates a process, in accordance with one embodiment, for fabricating a semiconductor structure such as the structures depicted in FIGS. 1-3. The process starts by providing a monocrystalline semiconductor substrate 22 comprising silicon or germanium. In accordance with a preferred embodiment, semiconductor substrate 22 is a silicon wafer having a (100) orientation. Substrate 22 is preferably oriented on axis or, at most, about 0.4° off axis. At least a portion of semiconductor substrate 22 has a bare surface, although other portions of the substrate, as described below, may encompass other structures. The term “bare” in this context means that the surface in the portion of substrate 22 has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process. In order to epitaxially grow a monocrystalline oxide layer 24 overlying monocrystalline substrate 22, the native oxide layer must first be removed to expose the crystalline structure of underlying substrate 22. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, substrate 22 is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer 24 of a monocrystalline oxide. The template provides the necessary chemical and physical properties to nucleate the crystalline growth of an overlying layer 24.

In accordance with an alternate embodiment, the native silicon oxide can be converted and the surface of substrate 22 can be prepared for the growth of a monocrystalline oxide layer 24 by depositing an alkaline earth metal oxide, such as strontium oxide or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate 22 surface. Again, this forms a template for the subsequent growth of an ordered monocrystalline oxide layer 24.

Following the removal of the silicon oxide from the surface of substrate 22, the substrate is cooled to a temperature in the range of about 200-800° C. and a layer 24 of strontium titanate is grown on the template layer by molecular beam epitaxy. The MBE process is initiated by opening shutters in the MBE apparatus to expose strontium, titanium, and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer 28 at the interface between underlying substrate 22 and the growing strontium titanate layer 24. The growth of silicon oxide layer 28 results from the diffusion of oxygen through the growing strontium titanate layer 24 to the interface where the oxygen reacts with silicon at the surface of underlying substrate 22. The strontium titanate grows as an ordered (100) monocrystal with the (100) crystalline orientation rotated by 45° with respect to the underlying substrate. Strain that otherwise might exist in strontium titanate layer 24 because of the small mismatch in lattice constant between silicon substrate 22 and the growing crystal 24 is relieved in amorphous silicon oxide intermediate layer 28.

After strontium titanate layer 24 has been grown to the desired thickness, the monocrystalline strontium titanate is capped by a template layer 30 that is conducive to the subsequent growth of an epitaxial layer of a desired compound semiconductor material 26. For the subsequent growth of a layer 26 of gallium arsenide, the MBE growth of strontium titanate monocrystalline layer 24 can be capped by terminating the growth with 1-2 monolayers of titanium, 1-2 monolayers of titanium-oxygen, or with 1-2 monolayers of strontium-oxygen. Following the formation of this capping layer, arsenic is deposited to form a Ti—As bond, a Ti—O—As bond, or a Sr—O—As bond. Any of these form an appropriate template 30 for deposition and formation of a gallium arsenide monocrystalline layer 26. Following the formation of template 30, gallium is subsequently introduced to the reaction with the arsenic and gallium arsenide 26 forms. Alternatively, gallium can be deposited on the capping layer to form a Sr—O—Ga bond, and arsenic is subsequently introduced with the gallium to form the GaAs.

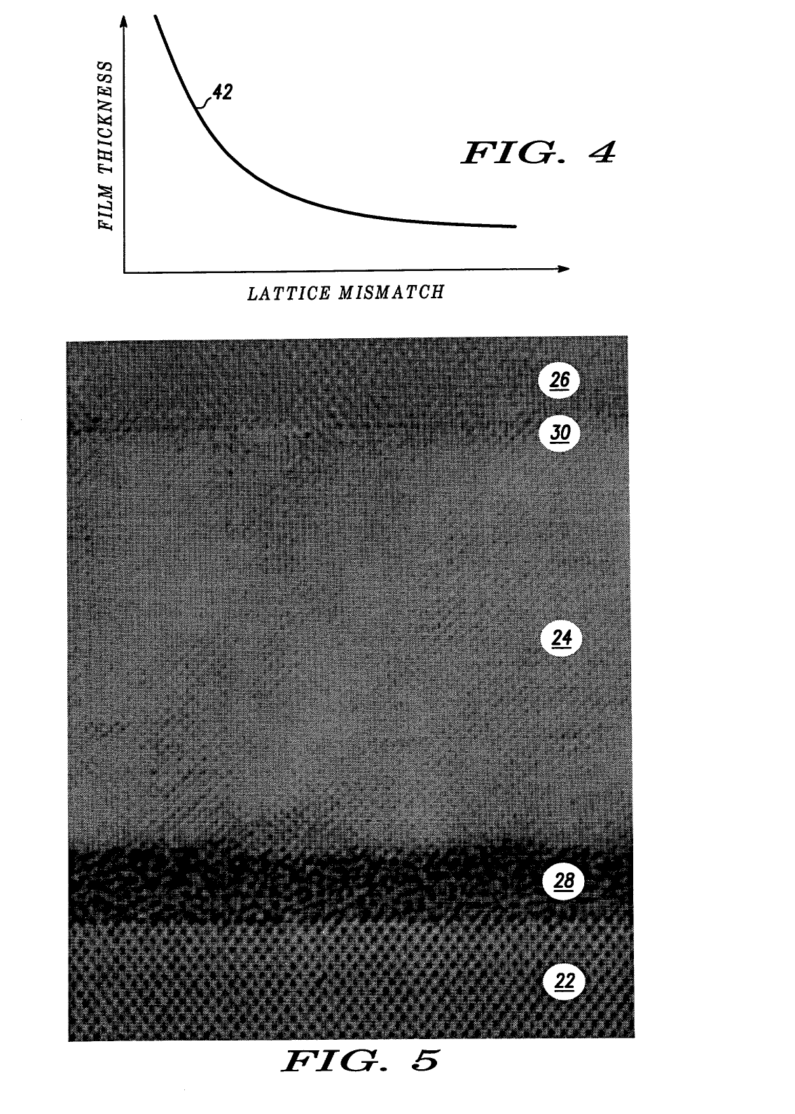

FIG. 5 is a high resolution Transmission Electron Micrograph (TEM) of semiconductor material manufactured in accordance with the present invention. Single crystal SrTiO3 accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

FIG. 6 illustrates an x-ray diffraction spectrum taken on a structure including GaAs compound semiconductor layer 26 grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying template layer 30 before the deposition of monocrystalline compound semiconductor layer 26. If additional buffer layer 32 is a compound semiconductor superlattice, such a superlattice can be deposited, by MBE for example, on the template 30 described above. If instead additional buffer layer 32 is a layer of germanium, the process above is modified to cap strontium titanate monocrystalline layer 24 with a final layer of either strontium or titanium and then by depositing germanium to react with the strontium or titanium. The germanium buffer layer 32 can then be deposited directly on this template 30.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and semiconductor layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

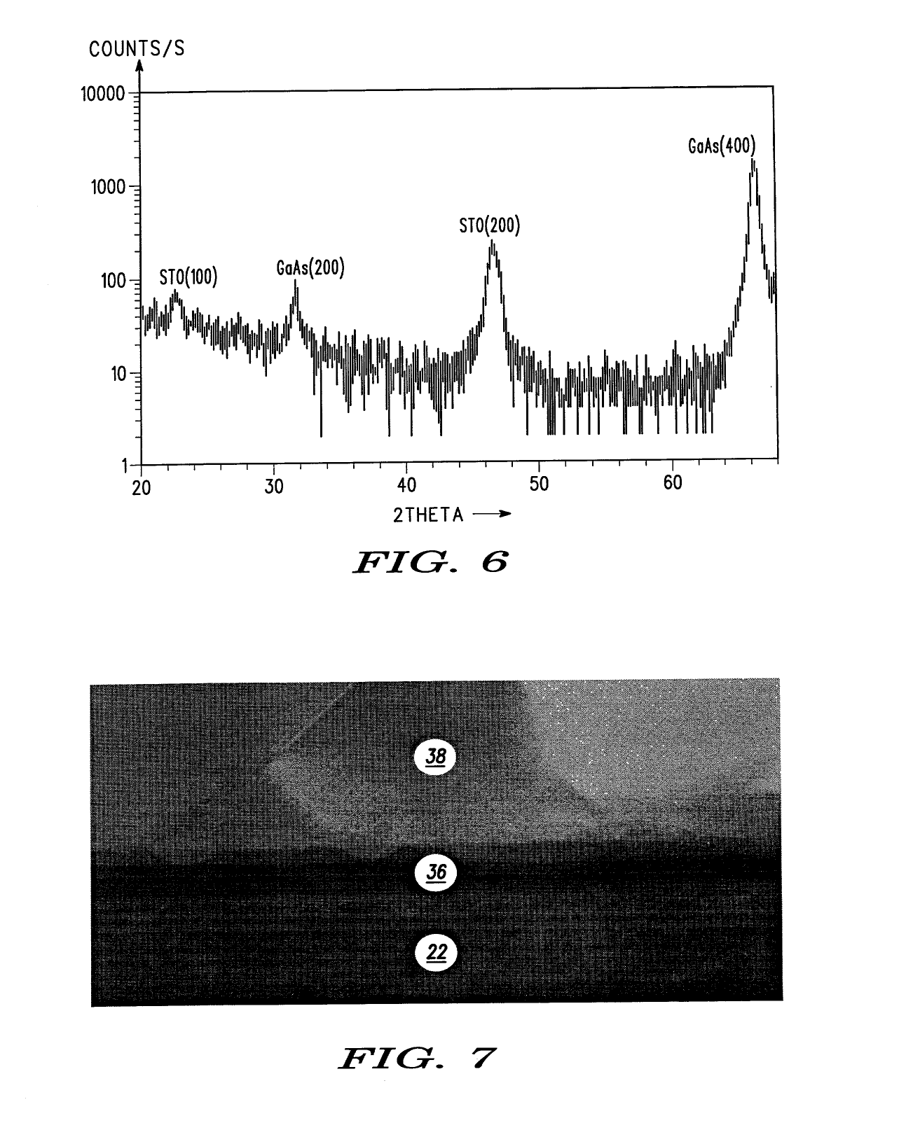

FIG. 7 is a high resolution Transmission Electron Micrograph (TEM) of semiconductor material manufactured in accordance with the embodiment of the invention illustrated in FIG. 3. In accordance with this embodiment, a single crystal SrTiO3 accommodating buffer layer was grown epitaxially on silicon substrate 22. During this growth process, an amorphous interfacial layer forms as described above. Next, GaAs layer 38 is formed above the accommodating buffer layer and the accommodating buffer layer is exposed to an anneal process to form amorphous oxide layer 36.

FIG. 8 illustrates an X-ray diffraction spectrum taken on a structure including GaAs compound semiconductor layer 38 and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate 22, an overlying oxide layer, and a monocrystalline gallium arsenide compound semiconductor layer 26 by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers 24 such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other III-V and II-VI monocrystalline compound semiconductor layers 26 can be deposited overlying monocrystalline oxide accommodating buffer layer 24.

Each of the variations of compound semiconductor materials 26 and monocrystalline oxide accommodating buffer layer 24 uses an appropriate template 30 for initiating the growth of the compound semiconductor layer. For example, if accommodating buffer layer 24 is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if monocrystalline oxide accommodating buffer layer 24 is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer 26, respectively. In a similar manner, strontium titanate 24 can be capped with a layer of strontium or strontium and oxygen, and barium titanate 24 can be capped with a layer of barium or barium and oxygen. Each of these depositions can be followed by the deposition of arsenic or phosphorus to react with the capping material to form a template 30 for the deposition of a compound semiconductor material layer 26 comprising indium gallium arsenide, indium aluminum arsenide, or indium phosphide.

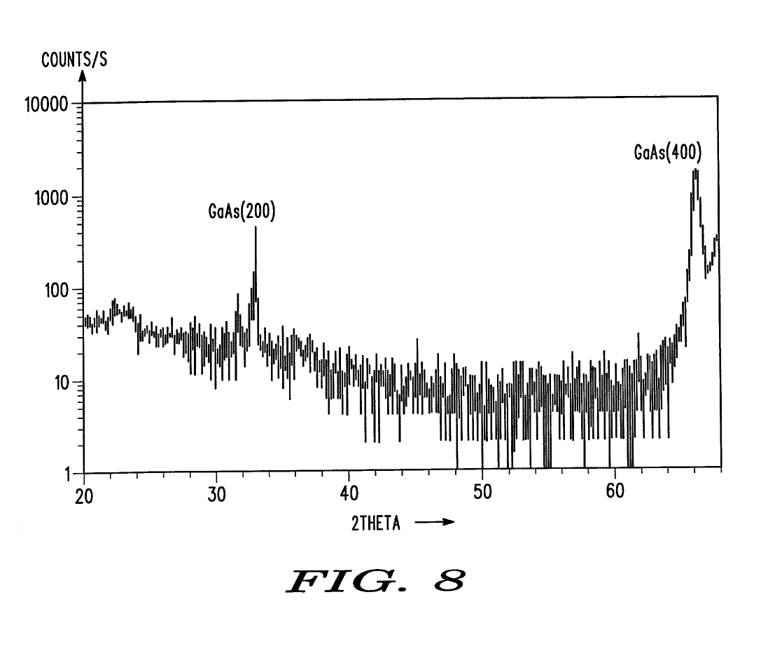

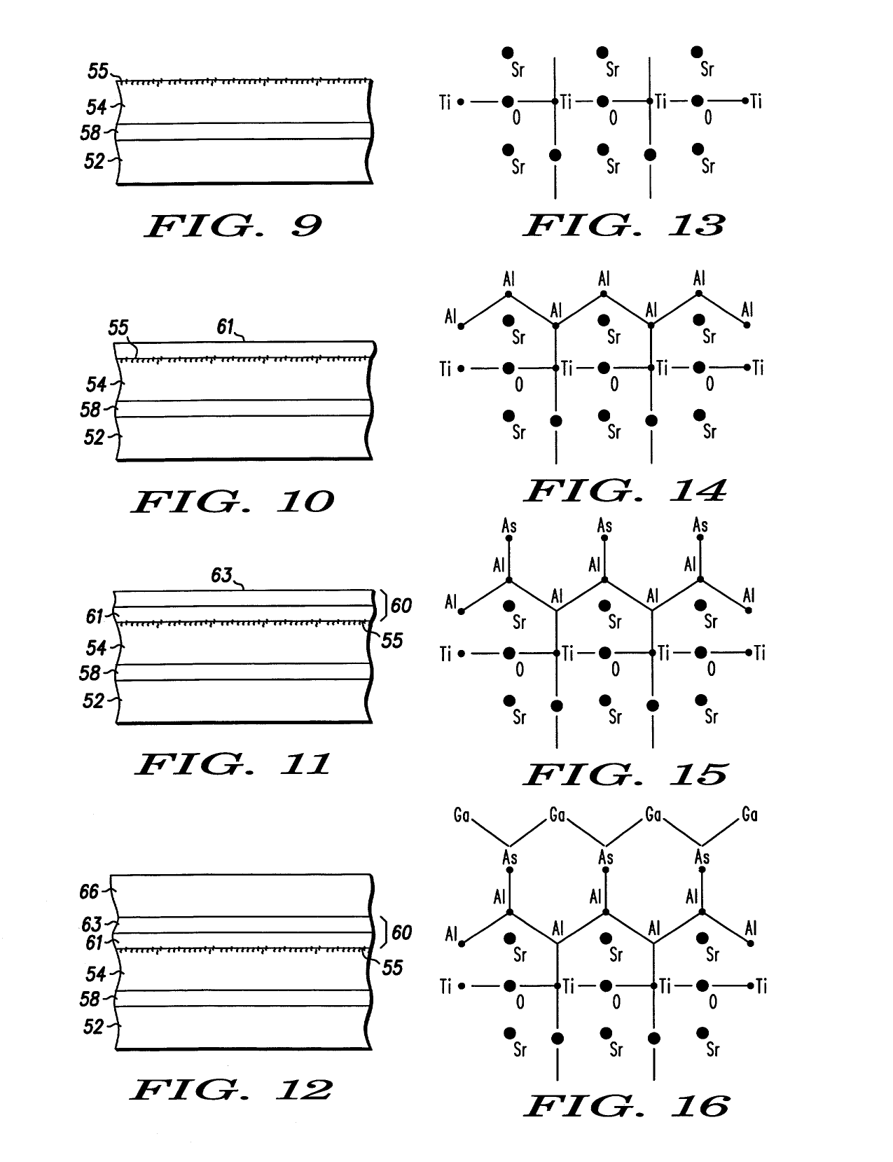

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference to layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In, and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb, and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, or the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C to form capping layer 82 and silicate amorphous layer 86. However, other suitable carbon sources may be used as long as the rapid thermal annealing step functions to a morphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, shown in FIG. 20, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from Groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphized to form a silicate layer which absorbs the strain between the layers. Moreover, unlike past use of a SiC substrate, this embodiment of the invention is not limited by wafer size which is usually less than 50mm in diameter for prior art SiC substrates.

The monolithic integration of nitride containing semiconductor compounds containing group III-V nitrides and silicon devices can be used for high temperature RF applications and opto-electronics. GaN systems have particular use in the photonic industry for the blue/green and UV light sources and detection. High brightness light emitting diodes (LEDs) and lasers may also be formed within the GaN system.

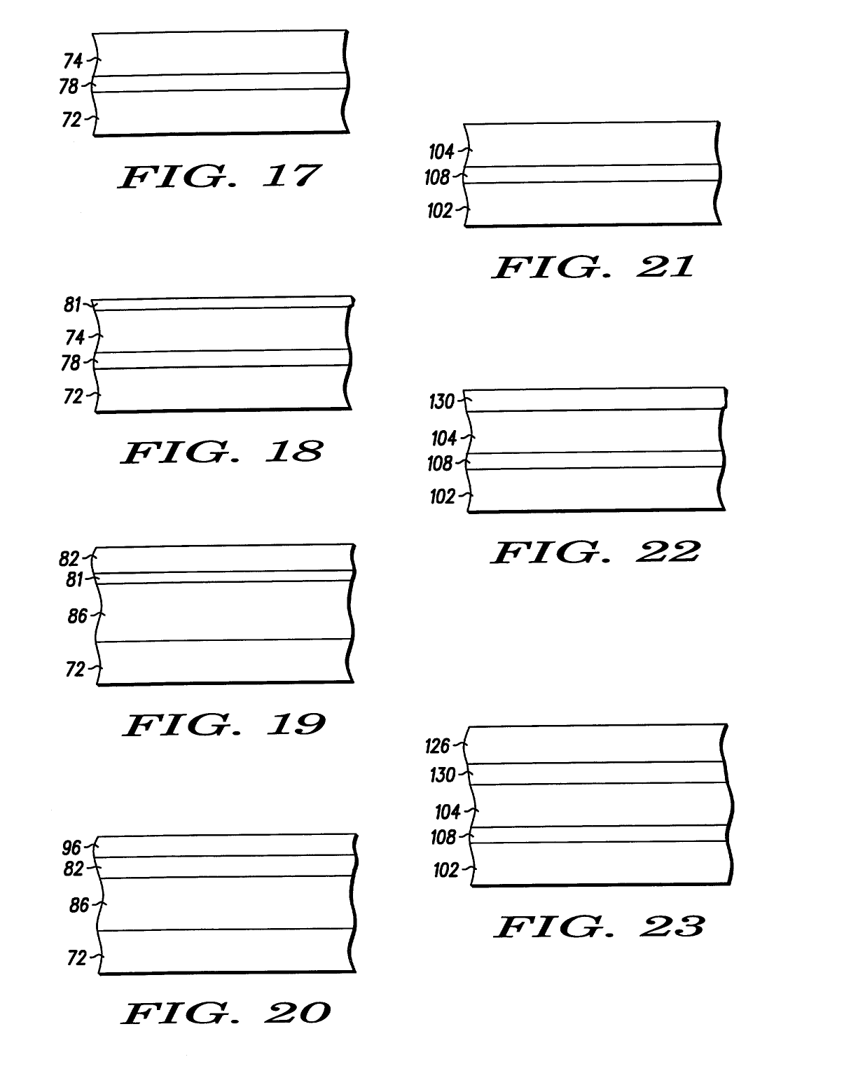

FIGS. 21-23 schematically illustrate in cross-section the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108, and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress buildup between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂.

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices, and integrated circuits including other layers such as metal and non-metal layers. More specifically, the invention includes structures and methods for forming a compliant substrate which is used in the fabrication of semiconductor structures, devices, and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

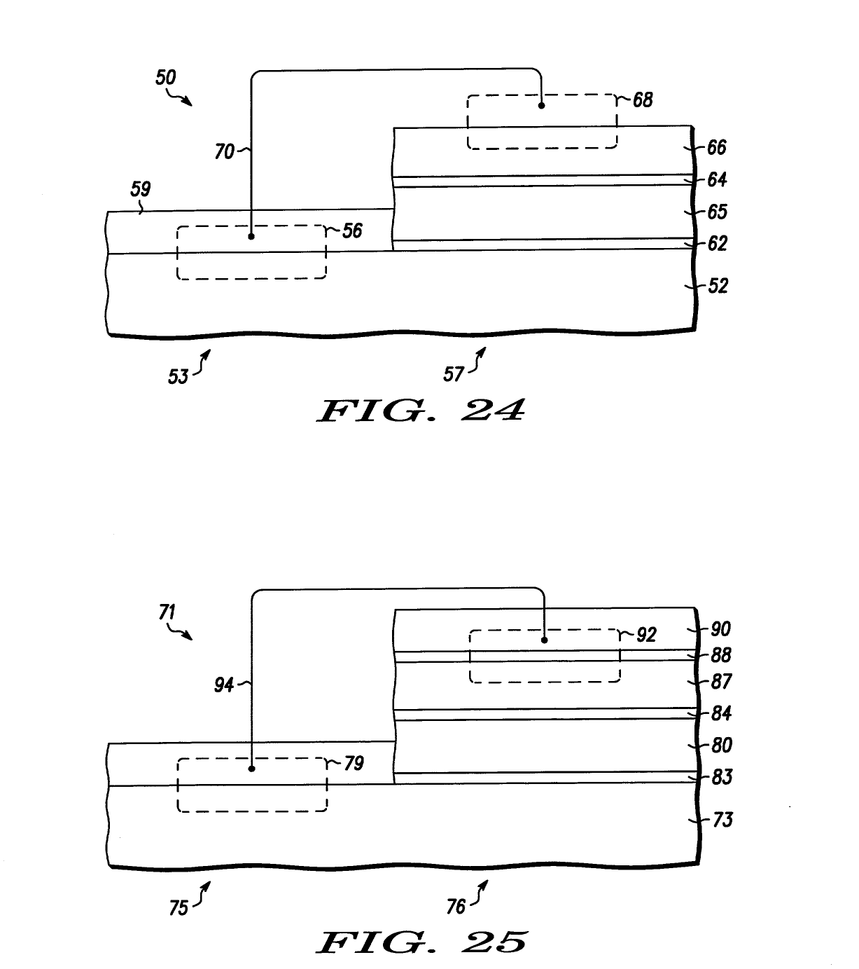

FIG. 24 illustrates schematically in cross-section a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. An electrical semiconductor component generally indicated by the dashed line 56 is formed, at least partially, in region 53. Electrical component 56 can be a resistor, a capacitor, an active semiconductor component such as a diode or a transistor or an integrated circuit such as a CMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of region 54 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition, the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 1-10 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide 66. Alternatively, strontium can be substituted for barium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical component schematically illustrated by the dashed line 79 is formed in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 86 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 87 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed at least partially in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a Group III-V compound and semiconductor component 92 is a radio frequency amplifier that takes advantage of the high mobility characteristic of Group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

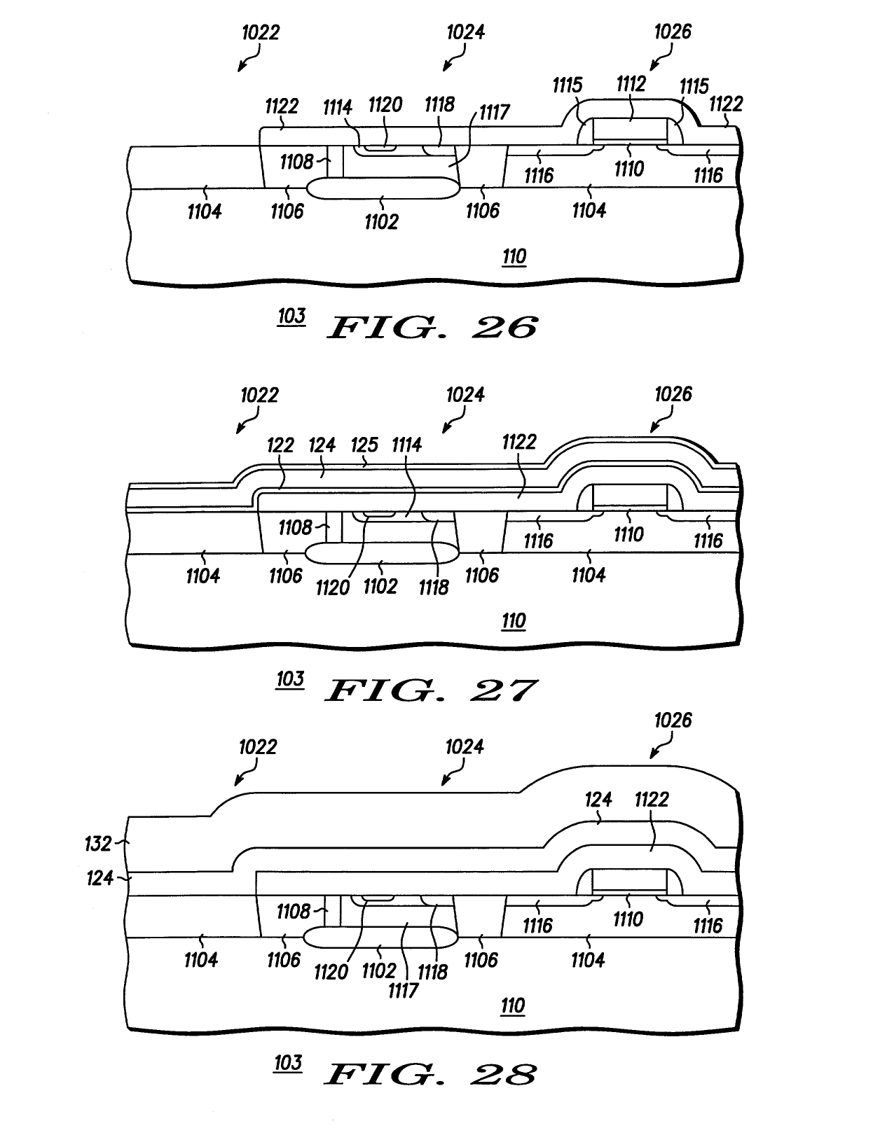

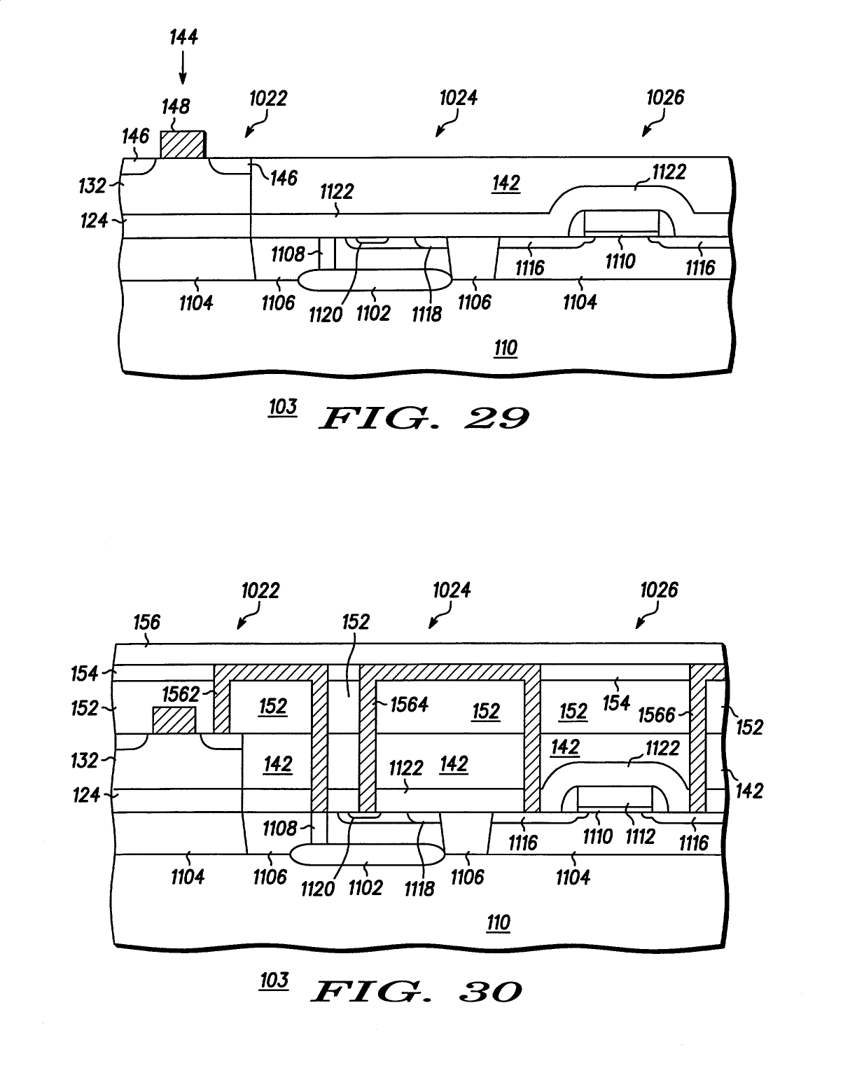

Attention is now directed to a method for forming exemplary portions of illustrative composite semiconductor structures or composite integrated circuits like 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N+buried region 1102. A lightly p-type doped epitaxial monocrystalline silicon layer 1104 is then formed over the buried region 1102 and the substrate 110. A doping step is then performed to create a lightly n-type doped drift region 1117 above the N+ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N+ doped regions 1116 and the emitter region 1120. N+ doped regions 1116 are formed within layer 1104 along adjacent sides of the gate electrode 1112 and are source, drain, or source/drain regions for the MOS transistor. The N+doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P+ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5.

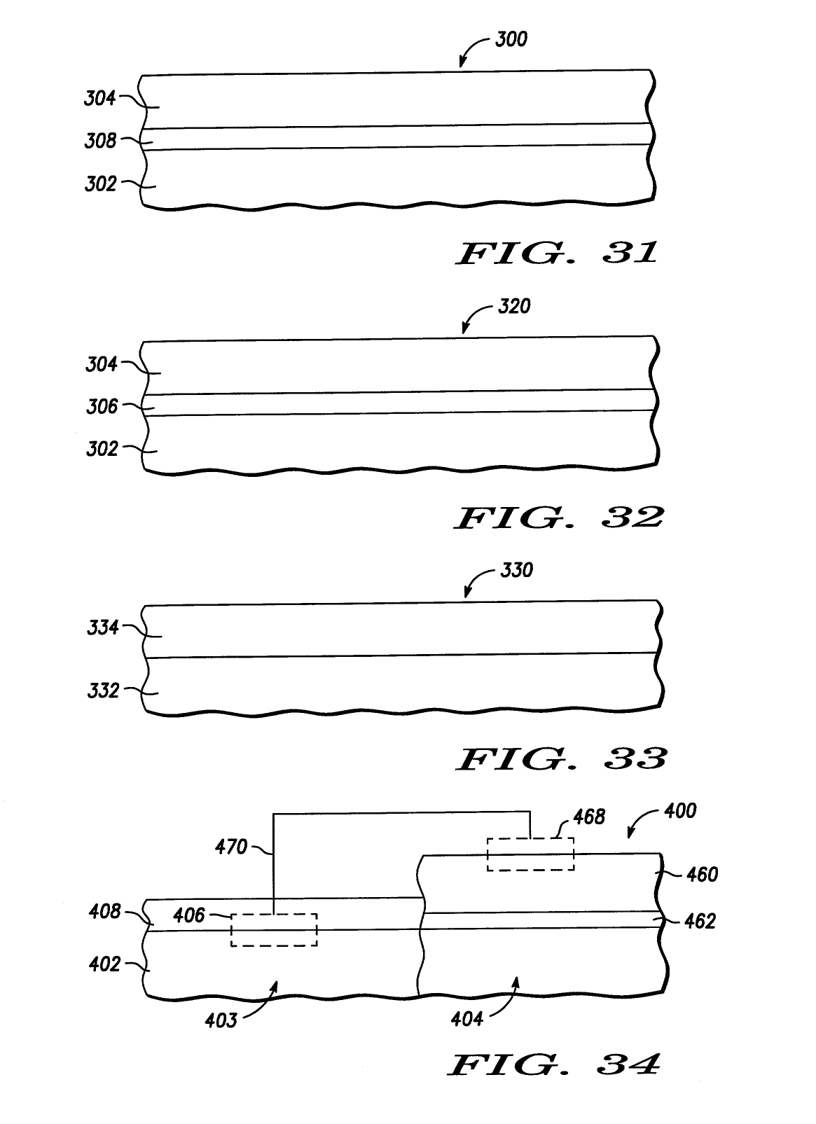

A monocrystalline compound semiconductor layer 132 is then epitaxially grown overlying the monocrystalline portion of accommodating buffer layer 124 as shown in FIG. 28. The portion of layer 132 that is grown over portions of layer 124 that are not monocrystalline may be polycrystalline or amorphous. The monocrystalline compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer 132, as discussed in more detail below in connection with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N+) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 102.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

Clearly, the embodiments of integrated circuits having compound semiconductor portions and Group IV semiconductor portions described above, are meant to illustrate what can be done and are not intended to be exhaustive of all possibilities or to limit what can be done. There is a multiplicity of other possible combinations and embodiments. For example, the compound semiconductor portion may include light emitting diodes, photodetectors, diodes, or the like, and the Group IV elemental semiconductor portion can include digital logic, memory arrays, and most structures that can be formed in conventional MOS integrated circuits. Further for example, as will be described in some detail below, either or both the compound semiconductor portion and the elemental semiconductor portion may include SAW devices and other electro-acoustic devices that are traditionally used as hybrid additions to signal processing circuitry. By using what is shown and described herein, it is now simpler to integrate devices that work better in compound semiconductor materials and/or other piezoelectric materials with other components that work better in Group IV semiconductor materials. This allows device sizes to shrink and the degree of monolithic integration to increase with an attendant increase in yield and reliability. Manufacturing costs may also decrease from economies of scale.

Although not illustrated, a monocrystalline Group IV wafer can be used in forming only compound semiconductor electrical components over the wafer. In this manner, the wafer is essentially a “handle” wafer used during the fabrication of the compound semiconductor electrical components within a monocrystalline compound semiconductor layer overlying the wafer. Therefore, electrical components can be formed within III-V or II-VI semiconductor materials over a wafer of at least approximately 200 millimeters in diameter and possibly at least approximately 300 millimeters.

By the use of this type of substrate, a relatively inexpensive “handle” wafer overcomes the fragile nature of the compound semiconductor wafers by placing them over a relatively more durable and easy to fabricate base material. Therefore, an integrated circuit can be formed such that all electrical components, and particularly all active electronic devices, can be formed within the compound semiconductor material even though the substrate itself may include a Group IV semiconductor material. Fabrication costs for compound semiconductor devices should decrease because larger substrates can be processed more economically and more readily, compared to the relatively smaller and more fragile, conventional compound semiconductor wafers.

As mentioned earlier, additional embodiments of integrated circuits according to the present invention may include SAW devices and other electro-acoustic devices. Electro-acoustic devices exploit piezoelectric properties of the device material for signal processing. Piezoelectricity refers to the phenomena in which the electrical behavior of a material is coupled to the mechanical behavior of the material. Piezoelectricity is generally observed in anisotropic materials with a polar molecular structure. Common piezoelectricity materials are often crystalline materials or ceramics. Piezoelectric materials respond to applied oscillating electrical fields by internally generating mechanical (i.e., acoustic) waves. Reciprocally, mechanical stress or strain applied to piezoelectric materials generates electric fields in them. The strength of the coupling between the electrical behavior and the mechanical behavior varies from material to material. This coupling strength, commonly referred to as the piezoelectric coupling factor K, is used as a measure of the piezoelectric properties of materials. The coupling factor K of a material depends on details of its polar molecular structure and often also on its crystal orientation. The design, size, functionality and performance characteristics of electro-acoustic devices depend on the piezoelectric properties (characterized, for example, by coupling factor K) of the device material used.

FIGS. 31-33 illustrate schematically, for example, monolithic structures 300, 320 and 330 which may be relevant or useful in connection with certain embodiments of the present invention for integrating electro-acoustic devices with semiconductor devices.

FIG. 31 illustrates schematically in cross-section a portion of monolithic structure 300 according to an embodiment of the invention. Structure 300 includes a monocrystalline substrate 302, and a piezoelectric layer 304. In accordance with one embodiment, structure 300 also includes an amorphous intermediate layer 308 positioned between substrate 302 and piezoelectric layer 304. Amorphous intermediate layer 308 helps to relieve the lattice-mismatch induced strain in piezoelectric layer 304. By doing so, layer 308 aids in the growth of good crystalline quality piezoelectric layer 304 with a suitable crystal orientation for high piezoelectric coupling strength.

Substrate 302, in accordance with one embodiment, is a monocrystalline semiconductor wafer, preferably of large diameter, similar to substrate 22 described earlier with reference to FIGS. 1-3. Preferably substrate 302 is a wafer containing silicon or germanium, and most preferably is a high quality monocrystalline silicon wafer as used in the semiconductor industry. Substrate 302 may be a bare unprocessed wafer or may be a wafer which has been already partially or fully processed to build buried device elements, for example, buried doped regions, into its surface. Substrate 302 also may be a wafer with limited bare surface portions with other portions of the wafer encompassing other structures.

Piezoelectric layer 304 is preferably formed of piezoelectric oxide or nitride material that is epitaxially grown on the underlying substrate 302. In accordance with one embodiment, amorphous intermediate layer 308 is grown on substrate 302 at the interface between substrate 302 and the piezoelectric layer 304 by the oxidation of substrate 302 during the growth of layer 304.

Piezoelectric layer 304 is a piezoelectric oxide or nitride material selected for having a piezoelectric coupling strength factor K suitable for making electro-acoustic devices. For example, the material could be a piezoelectric oxide or nitride. Materials that may be suitable for piezoelectric layer 304 include metal oxides with high piezoelectric strength such as certain alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, zinc oxide and gadolinium oxide. Additionally, piezoelectric nitrides such as aluminum nitride or other nitrides may also suitable for piezoelectric layer 304. Most if not all of these piezoelectric materials may have crystal orientations and/or lattice spacings, which are substantially different from those of silicon. These differences cause direct epitaxial growth of these materials (especially of thick layers, FIG. 4) to result in poor quality piezoelectric material. In accordance with the invention, growth of good quality piezoelectric layer 304 on silicon, as mentioned earlier, is accomplished by use of an amorphous intermediate layer 308 which absorbs or relieves lattice-mismatch induced strain in the piezoelectric/substrate epitaxial structure.

Oxide or nitride material used to form piezoelectric layer 304, in addition to considerations of piezoelectric strength, may also be chosen with consideration for its lattice compatibility with a superlayer of semiconductor material that may be epitaxially grown on top of layer 304. If the material for piezoelectric layer 304 is so chosen (e.g., strontium barium titanate), piezoelectric layer 304 may serve the same purpose as accommodating buffer layer 24, accommodating buffer layer 54, or accommodating buffer layer 104 in the fabrication of composite semiconductor structures described earlier with reference to FIGS. 1-2, FIGS. 9-12, and FIGS. 21-23, respectively. In such case structure 300 forms a subset of the composite Group IV, Group III-V, Group II-VI, or clathrate type semiconductor structures of the embodiments of the invention described earlier.

In a preferred embodiment of monolithic structure 300, piezoelectric layer 304 is a strontium barium titanate layer (i.e., Sr_{z}Ba_{1-z}TiO₃ where z may have a chosen value between from 0 to 1). Any suitable growth methods using MBE, CVD, MOCVD, MEE, ALE, PVD, CSD, PLD techniques and the like may be used. For example, the growth methods using MBE described earlier for growing accommodating layer 24 (e.g., FIGS. 1-3) may be used to grow strontium barium titanate layer 304. Piezoelectric layer 304 may have a thickness in the range from a few hundred nanometers to tens of microns. The thickness of piezoelectric layer 304 may be suitably chosen for its use in electro-acoustic devices.

FIG. 32 schematically illustrates in cross-section a portion of a monolithic structure 320 in accordance with another exemplary embodiment of the invention. Structure 320 differs from structure 300 in that piezoelectric layer 304 is separated from substrate 302 by an intermediate accommodating layer 306. Piezoelectric structure 320 may be made of piezoelectric materials such as zinc oxide and aluminum nitride. Accommodating layer 306 may be made of crystalline or amorphous material chosen with consideration for strain relief and lattice matching necessary for growth of good quality piezoelectric layer 304. In one embodiment, amorphous layer 306, starts out as a crystalline layer. A thin piezoelectric layer 304 is first grown on layer 306 utilizing layer 306's crystallinity to first initiate or establish the crystalline habit of piezoelectric layer 304. Then, structure 300 is heated to soften or melt layer 306, making layer 306 amorphous. Amorphous layer 306 may be more suitable for relieving the lattice-mismatch induced mechanical stress or strain in grown thin piezoelectric layer 306. Then, further growth of a thicker piezoelectric layer 304 may continue stress free. Accommodating layer 306 may, for example, be made up of any of the oxides previously discussed, for example, with reference to FIGS. 1 and 2. Accommodating layer 306 is preferably an amorphous silicate layer 20 to 100 Angstroms thick.

Monolithic structure 320 may be formed, for example, by extending previously described methods for forming silicon carbide capping layer 82 on top of amorphous silicate layer 86 with reference to the composite semiconductor structures illustrated in FIGS. 17-20. The silicon carbide cap layer may be used as a base on which to form a thicker piezoelectric layer 304 made of commonly used piezoelectric films such as zinc oxide or aluminum nitride films. In processes for forming structure 320, formation of a silicon carbide cap layer on top of amorphous silicate layer 306 may be followed, for example, by growth of additional silicon carbide to form a thicker silicon carbide layer 304. Thick silicon carbide layers may be useful for some unconventional piezoelectric material use.

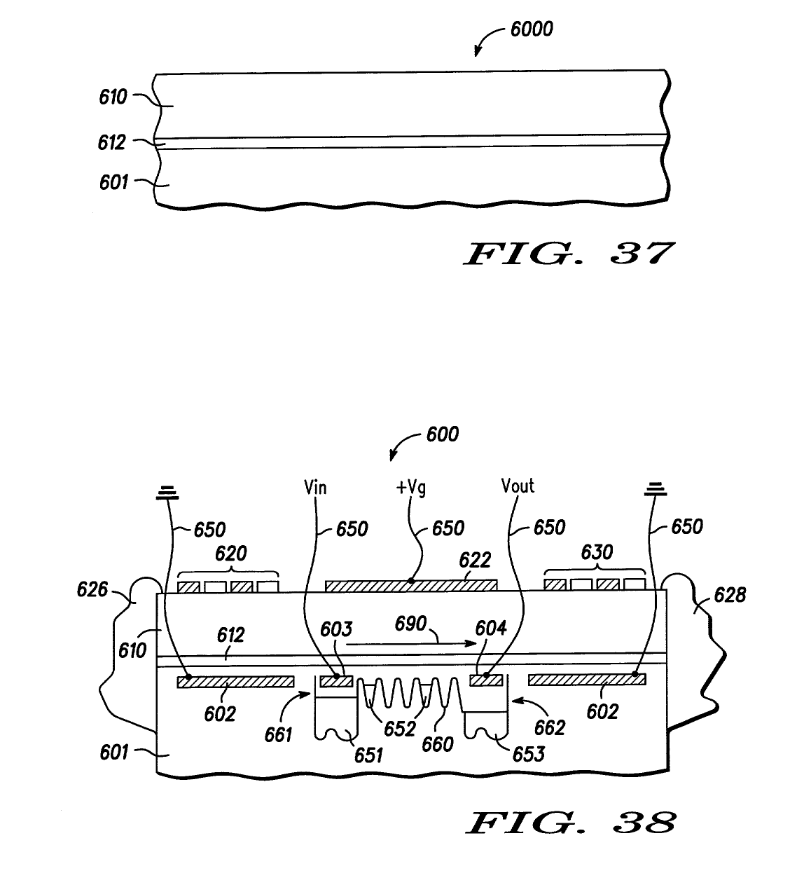

For some other desirable piezoelectric materials for layer 304 such as lithium niobate or lithium tantalate, use of a silicon carbide or other cap layer is not required. Piezoelectric layer 304 made of lithium niobate and lithium tantalate may be formed on layer 306 without use of an intervening cap layer (as will be described below in greater detail with reference to FIG. 37).

FIG. 33 schematically illustrates in cross-section a portion of a monolithic structure 330 in accordance with yet another exemplary embodiment of the invention. Structure 330 includes piezoelectric layer 334 grown or deposited on semiconductor layer 332. Semiconductor layer 332 may be any of the uppermost monocrystalline semiconductor layers of the composite semiconductor structures described earlier with reference to FIGS. 1-3, 9-12, and 17-21. Semiconductor layer 332 may, for example, be GaAs layer 26 described in Example 1 above. Piezoelectric layer 334 may, for example, be formed from aluminum nitride, zinc oxide or any other suitable piezoelectric material. Piezoelectric layer 334 may be formed using any suitable deposition or growth technique. A suitable template layer or accommodating layer (not shown) may first be formed on the top surface of layer 332 if appropriate or advantageous for forming good quality piezoelectric layer 334. Piezoelectric layer 334 may have a thickness ranging from a few hundred nanometers to tens of microns. The thickness of piezoelectric layer 334 like that of piezoelectric layer 304 mentioned earlier may be suitably chosen for its use in electro-acoustic devices.

FIGS. 34 and 36 illustrate schematically in cross-section the utility of the monolithic structure embodiments described above in integrating piezoelectric-material based electro-acoustic devices with other semiconductor devices. With reference to FIG. 34, monolithic structure 400 includes a monocrystalline semiconductor substrate 402, which preferably is a monocrystalline silicon wafer. Monocrystalline semiconductor substrate 402 includes two regions, a semiconductor region 403 and a piezoelectric region 404. An electrical semiconductor component generally indicated by the dashed line 406 is formed, at least partially, in region 403. Electrical component 406 can be a resistor, a capacitor, an active semiconductor component such as a diode or a transistor or an integrated circuit such as a CMOS integrated circuit. For example, electrical semiconductor component 406 can be a CMOS integrated circuit configured to perform digital signal processing or another function for which silicon integrated circuits are well suited. The electrical semiconductor component in region 403 can be formed by conventional semiconductor processing techniques that are well known and widely practiced in the semiconductor industry. A layer of insulating material 408 such as a layer of silicon dioxide or the like may overlie electrical semiconductor component 406.

Insulating material 408 and any other layers that may have been formed or deposited during the processing of semiconductor component 406 in region 403 are removed from the surface of region 404 to provide a bare silicon surface in the latter region. A layer of barium or barium and oxygen is deposited onto the surface of region 404 to reduce native oxides formed on the surface and to form a first template layer (not shown). In accordance with one embodiment, a piezoelectric layer is formed overlying the template layer by a MBE process. Reactants including strontium, barium, titanium and oxygen may be deposited onto the template layer to form piezoelectric layer 460. Initially during the deposition, the partial pressure of oxygen is kept near the minimum necessary for stoichiometric reaction with the deposited strontium, barium and titanium to form a thin piezoelectric strontium barium titanate layer. Subsequently, the partial pressure of oxygen is increased to provide an over pressure of oxygen, which allows some oxygen to diffuse through the growing piezoelectric oxide layer 460. The oxygen diffusing through the growing strontium barium titanate layer reacts with silicon at the surface of region 404 to form an amorphous silicon oxide layer 462 on second region 404 at the interface between silicon substrate 402 and the piezoelectric layer 460.

An electro-acoustic component, generally indicated by a dashed line 468 is formed at least in part in piezoelectric layer 460. Metallic conductors schematically indicated by the line 470 can be formed to electrically connect component 468 and component 406, thus implementing an integrated device that includes at least one component formed in silicon substrate 402 and one component formed using piezoelectric layer 460.

Electro-acoustic component 468 may be any suitable passive SAW component. Suitable SAW components may, for example, be transducers, dispersive filters, band pass filters, convolvers, delay lines, and resonators. Electro-acoustic component 468 may be formed by processing steps conventionally used, for example, in the fabrication of SAW devices having interdigitated transducers. With continued reference to FIG. 34, FIG. 36 shows schematically in plan view, for example, real time signal convolver 480 that may be formed in piezoelectric layer 460. Conventional patterning and metal deposition processes may be used to form interdigitated input transducer 481, interdigitated reference transducer 482, and output transducer 483. Metallic conductors schematically indicated by the lines 471, 472, and 473 can be formed for connection of input signals, reference signals, and output signals, respectively, to and from semiconductor components such as component 406. In an alternative embodiment, some or all of transducers 481, 482, and 483 may be formed on surface of substrate 402 in region 404 prior to formation of piezoelectric layer 460. Conventional semiconductor processing such as dopant diffusion or ion implantation may be used to provide buried conductive regions which may serve as SAW device transducers 481, 482, and 483.

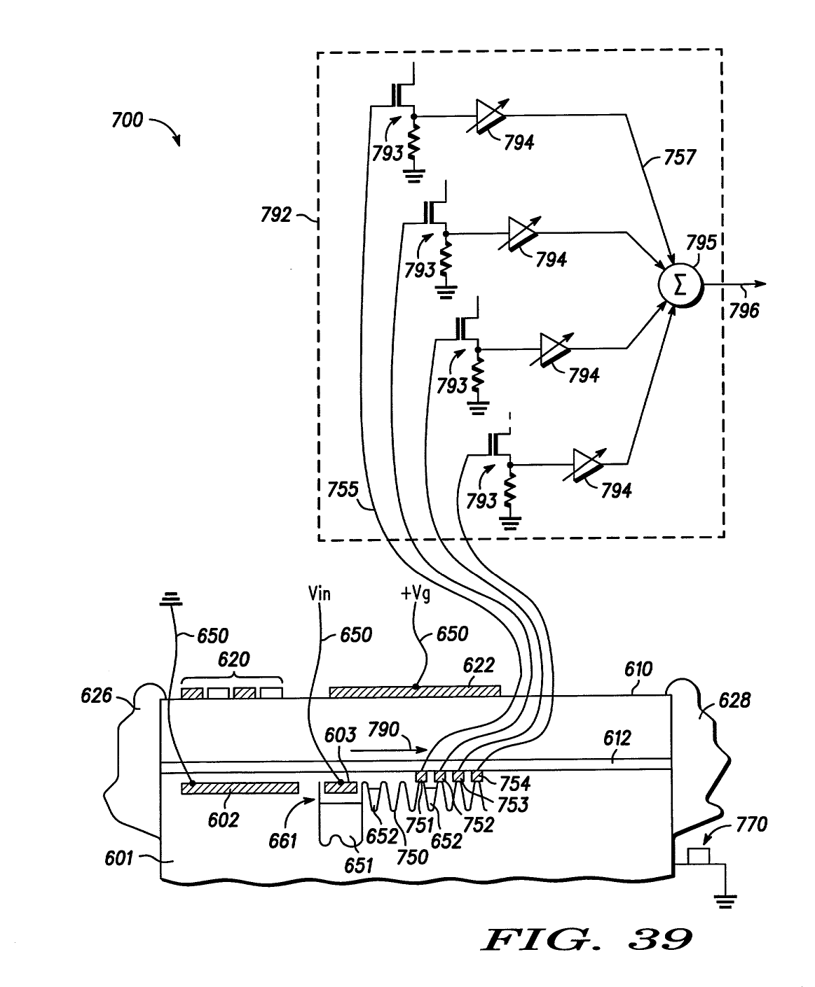

Electro-acoustic component 468 also may be an active component such as an acoustic charge transfer (ACT) device (e.g., ACT device 600 or 700 described below with reference to FIGS. 38 and 39, respectively). Further, component 468 also may be any other device that utilizes the interaction of acoustic waves and their associated electric and magnetic fields in piezomaterials with the electrical properties of proximal semiconductors.

Although illustrative structure 400 has been described as a structure formed on a silicon substrate 402 and having a strontium barium titanate piezoelectric layer 460, similar paired semiconductor-piezoelectric monolithic structures may be fabricated in accordance with the invention using other combinations of substrate materials and piezoelectric materials. Any of the materials which have which been mentioned elsewhere in this disclosure may be used.

FIG. 36 illustrates a monolithic structure 500 in accordance with a further embodiment. Structure 500 uses a monocrystalline semiconductor substrate 502, which may, for example, be a monocrystalline silicon wafer. Structure 500 includes regions 505, 506, 507, and 508.

An electrical component schematically illustrated by the dashed line 510 is formed in region 506 using conventional silicon device processing techniques commonly used in the semiconductor industry. Semiconductor elements of an electro-acoustic component 509 which is schematically illustrated by the dashed line 509, also may be formed in region 505 using conventional silicon device processing techniques. The semiconductor elements of component 509 may, for example, be heavily doped buried regions that can be used as transducer electrodes in a SAW device. Using epitaxial material growth methods similar to those described earlier, a piezoelectric oxide layer 520 and an intermediate amorphous silicon oxide layer 522 are formed in region 505 overlying semiconductor elements of electro-acoustic component 509, and in regions 507 and 508. Piezoelectric oxide layer 520 is formed with a high monocrystalline quality enabling its use as an accommodating layer for subsequent growth of compound semiconductor superlayer 526. A template layer 524 is formed overlying piezoelectric (monocrystalline) oxide layer 520 in regions 507 and 508 of substrate 502. Superlayer 526 may, for example, be a monocrystalline compound semiconductor formed directly on template layer 524 or may, for example, be a monocrystalline compound semiconductor formed on intermediate buffer layers (not shown). Processes described earlier in the context of forming composite Group IV, Group III-V, Group II-VI, or clathrate type semiconductor structures (e.g., FIGS. 1-3, 9-12 and 17-25) may be used with suitable modifications as appropriate to form template layer 524 and superlayer 526. A piezoelectric layer 530 is formed on top of superlayer 526 in region 508 of substrate 502. Layer 530 may, for example, be an aluminum nitride layer or a zinc oxide layer formed using CVD or PVD techniques.

A semiconductor component generally indicated by a dashed line 511 is formed at least partially in superlayer 526 in region 507. Further, an electro-acoustic component generally indicated by a dashed line 512 is formed at least partially in piezoelectric layer 530 in region 508. In accordance with one embodiment, superlayer 526 is formed from a Group III-V compound semiconductor, semiconductor component 511 is a radio frequency transceiver that takes advantage of the high mobility characteristic of Group III-V component materials, and electro-acoustic component 512 is a passive SAW device.

Electrical interconnections schematically illustrated by lines 540 electrically interconnect components 509, 510, 511 and 512. Monolithic structure 500 thus integrates different semiconductor and electro-acoustic components that take advantage of the unique properties of different semiconductor and piezoelectric materials in monolithic structure 500.

The monolithic structures of the invention enable integration of conventional devices whose design generally may be optimized to account for the physical properties of the individual material systems from which the devices are traditionally made. For example, DRAM devices in a monolithic structure may be optimized to exploit the properties of silicon material while MESFET devices in the monolithic structure may be optimized to exploit, for example, the physical properties of GaAs material. Additionally, the monolithic structures of the invention enable alternative device designs which exploit the physical properties of more than one traditional material system in the monolithic structures. These alternative devices may have superior functionality and/or performance compared to the traditional devices.

An alternative device may, for example, be an ACT device, which exploits the physical properties of both silicon and an overlying piezoelectric layer. Electronic charge transport in an ACT device may be understood by recognizing that acoustic waves traveling in piezoelectric material are accompanied by piezoelectrically-coupled traveling oscillating electric fields. Electric fields imposed on semiconductor material can create electric field potential quantum wells, which can trap or hold electronic charge. These potential quantum wells move along with the traveling acoustic wave at the same speed as the acoustic wave. The moving potential quantum wells transport trapped charge across the semiconductor material in the direction of the acoustic wave. Traditional ACT devices are formed in polar compound semiconductors which are also piezoelectric, albeit weakly so, such as GaAs. Piezoelectric transduction of acoustic waves in GaAs ACT device material also generates traveling potential quantum wells in the same GaAs device material for electronic charge transport.

The use of material such as GaAs with dual piezoelectric and semiconducting properties in ACT devices may simplify device processing, but generally results in unsatisfactory device performance. The unsatisfactory performance is at least in part due the weak piezoelectric coupling strength of such materials. GaAs, for example, has a coupling strength K of only about 0.06%. Because of this low K value, high input powers (100 mW to 1 W) must be used in GaAs ACT devices to transduce acoustic waves of sufficient strength to create associated potential quantum wells suitable for electronic charge transport. Such high input power devices are increasingly incompatible with battery powered circuitry usage. GaAs ACT devices are also undesirably noisy at low frequencies, for example, below 1 MHz, due to the poor 1/f noise characteristics of GaAs.

An embodiment of the monolithic structures of the present invention provides an ACT device which combines, for example, the superior 1/f noise properties of non-piezoelectric silicon semiconductor with the superior piezoelectric coupling strengths of certain metallic oxides and nitrides mentioned earlier.

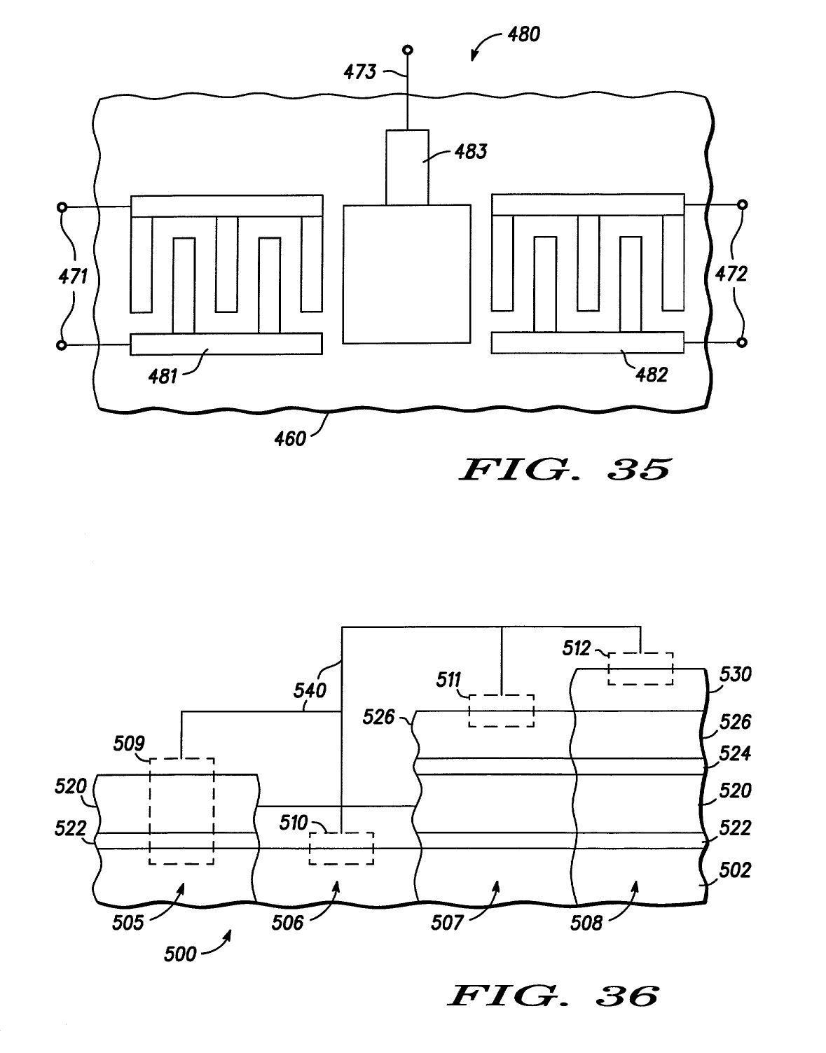

A preferred monolithic structure 6000 for fabrication of ACT devices (or other electro-acoustic devices) is shown in FIG. 37. Structure 6000 may be incorporated into structures 400 and 500 for making integrated circuits (FIGS. 34-36). A suitably doped or undoped silicon wafer, which may have been previously processed to build buried device elements, is used as a starting substrate 601 for fabricating the structure 6000. Preferably, piezoelectric layer 610 is made from piezoelectric material that has high piezoelectric coupling strength K, such as lithium niobate or lithium tantalate. These materials usually have a large lattice mismatch with silicon. In accordance with the invention, good quality crystalline layers of such materials may be grown on silicon by using an intermediate strain-relief layer 612 to bridge the lattice mismatch between silicon and piezoelectric layer 610. Strain-relief layer 612 may, for example, be made from Sr_{z}Ba_{1-z}TiO₃. Using, for example, previously described methods such as the deposition and reaction with barium, strontium or titanium metal to reduce the native oxide on the surface of a silicon wafer, the surface of substrate 601 is conditioned for epitaxial growth. A crystallographically-oriented epitaxial layer 612 of Sr_{z}Ba_{1-z}TiO₃, where z may have a chosen value between from 0 to 1, is grown on the surface of substrate 601. An appropriate template, as described earlier, may be used to seed the growth of crystalline Sr_{z}Ba_{1-z}TiO₃.

The crystalline Sr_{z}Ba_{1-z}TiO₃ layer 612 itself serves as another seed layer to initiate growth of a thin piezoelectric crystalline layer 610. The lattice spacing and crystal orientation of Sr_{z}Ba_{1-z}TiO₃ are a function of its composition. A suitable value of z is chosen so that Sr_{z}Ba_{1-z}TiO₃ layer 612 has a lattice spacing and crystallographic orientation close to that of a desired crystalline material piezoelectric layer 610. The desired orientation of layer 610 may, for example, be the particular orientation associated with the maximum piezoelectric coupling strength K of the piezoelectric crystal used for layer 610. An amorphous silicon oxide layer (described earlier, but not shown FIG. 37) may form at the interface of the Sr_{z}Ba_{1-z}TiO₃ layer 612 and substrate 610 due to oxidation of the silicon substrate surface by oxygen diffusing from the growth ambient.

A thin layer 610 of crystalline piezoelectric material is then grown in its desired orientation on layer 612. Because of possibly inexact lattice matching between the crystalline piezoelectric material in its desired orientation and crystalline Sr_{z}Ba_{1-z}TiO₃ layer 612, only a thin piezoelectric layer 610 may be grown substantially defect-free. The growth of layer 610 is interrupted while its thickness is still below the critical thickness for defect-free growth (FIG. 4).

Piezoelectric layer 612 is generally made of materials (such as lithium niobate or tantalate) which have a higher melting point than the melting point of crystalline Sr_{z}Ba_{1-z}TiO₃ layer 612. By suitable treatment, for example, by heating substrate 601 to a suitable temperature at or below the melting temperature of Sr_{z}Ba_{1-z}TiO₃, layer 612 is softened or amorphized. The heat treatment temperature is suitably chosen so as not to substantially or significantly affect the thin piezoelectric layer 610 itself. The softening or amorphization of layer 612 results in what may be called a thin piezoelectric “floating crystal” layer 610 on top of amorphous layer 612. The lattice structure of floating layer 610 is decoupled from the lattice structure of substrate 610. This decoupling removes lattice-mismatch/elasticity constraints (FIG. 4) on the defect-free growth thickness of layer 610. Growth of crystalline piezoelectric layer 610 may, thereafter, be resumed. Layer 610 may be grown to a desired thickness while maintaining the proper crystal orientation desired for piezoelectric coupling strength. The growth thickness of this now floating crystal grown on the now amorphous layer 612, may substantially exceed the critical thickness that otherwise applies to piezoelectric material grown on the former crystalline Sr_{z}Ba_{1-z}TiO₃ layer 612, without significantly degrading crystal quality.

The removal of thickness constraints on the growth of good quality piezoelectric layer provides flexibility and choice in the design of monolithic structure 6000. Piezoelectric layer 610 may be made available for device fabrication in a range of thickness as appropriate for specific electro-acoustic device applications.

FIG. 38 is a schematic representation of the structure of an exemplary ACT device 600 fabricated using exemplary structure 6000 (FIG. 37). FIG. 38 shows portions of device 600 in cross-section and also includes a figurative representation of the potential field and electronic charge distribution in device 600. Device 600 is formed on doped silicon substrate 601. Substrate 601, for example, may be p-doped silicon.

Device 600 has semiconductor elements and piezoelectric elements. The semiconductor elements of device 600 include laterally spaced-apart input diode 603 and output diode 604 formed at or near the top surface of substrate 601. Device 600 may also optionally include AC ground plates 602. The semiconductor elements of device 600 may be formed using conventional silicon processing techniques. Optional AC ground plates 602 may, for example, be heavily doped buried regions formed by N⁺ dopant diffusion. Diodes 603 and 604 may, for example, be formed by ion implantation and annealing of suitable n-type dopants.

A piezoelectric material layer 610 and an intermediate strain-relief layer 612 are formed on top surface of substrate 601 as described above (FIG. 39) Layer 610 overlies the semiconductor elements of device 600. The material of piezoelectric layer 610 is suitably selected to have strong piezoelectric coupling strength and also to have crystalline growth compatibility with substrate 601. It will be understood that the growth compatibility refers not only to the rare instances where direct growth is possible, but also to instances where crystalline growth to thickness required for device fabrication is possible only in accordance with this invention by use of intermediate strain-relief 612 or use of other previously described accommodating layers. Piezoelectric layer 610 may, for example, be any of the piezoelectric materials mentioned earlier in this disclosure and most preferably made of a strong piezoelectric material such as lithium niobate or lithium tantalate. Strain-relief layer 612 may, for example, be an amorphized strontium barium titanate layer. Piezoelectric layer 610 itself may be composed of crystalline strontium barium titanate. In which case strain-relief layer 612 is an amorphous silicon layer formed during growth of a strontium barium titanate layer 610.

The thickness of layer 610 may range from a few hundred nanometers to tens of microns. Piezoelectric layers of good crystalline quality and having a thickness of several microns thickness may be grown, for example, by any of the previously described methods. The desirable thickness of layer 610 depends on wavelength λ of an acoustic wave propagating in layer 610 during the operation of device 600. The thickness of layer 610 is preferably in the range of about 0.3 λ to about 0.7 λ. The acoustic wavelength λ is proportional to the frequency of a clock or signal driving device 600. For a clock frequency of about 500 MHz, a thickness of about 4 microns may be desirable.

Further, device 600 has an input SAW transducer 620 and a gate electrode 622 formed on the top surface of piezoelectric layer 610. Input SAW transducer 620 may be an interdigitated transducer designed for transducing an acoustic wave having a frequency corresponding to the frequency of the clock signal (not shown) driving transducer 620. Input transducer 620 may have a conventional SAW transducer design, for example, a 1-, 2-, or 3-phase transducer design, suitable for producing unidirectional acoustic waves propagating laterally in direction 690 (i.e., left to right in FIG. 38). Unidirectional propagating waves are desirable for device operation. With unidirectional waves electronic charge transport in device 600 takes place in single direction from input diode 603 to output diode 604. Optional acoustic absorber 628 may be placed on the right side of device 600 to prevent undesirable return reflections of the unidirectional acoustic waves bouncing off the right end of device 600. The return reflections are undesirable because they superimpose on the unidirectional left-to-right acoustic waves to form stationary standing waves, which do not transport charge. Optional output transducer 630 may be used to absorb a fraction of the acoustic waves traveling past output diode 604 and, thereby, to attenuate the strength of any reflected acoustic waves. Alternatively, input transducer 620 may have a simpler conventional design producing bi-directional acoustic waves (i.e., left to right, and right to left in FIG. 38). In this case, other known techniques may be used to attenuate propagation of the transduced acoustic waves in undesirable directions (i.e., right to left in FIG. 38). The known techniques include using an optional acoustic absorber 626 on the left side of device 600 and/or providing substrate 602 with a slightly off-axis cut edge orientation.

SAW transducers 620 and 630 may be traditional transducers formed by metal deposition. Gate electrode 622 disposed on layer 610 between transducers 620 and 630 may also be formed by metal deposition. Lines 650 schematically show electrical connections to various terminals or ports of device 600. These electrical connections 650 may be formed on substrate 601 using conventional semiconductor processing techniques.

In the operation of device 600, input and output diodes 603 and 604 are reverse biased, and an input clock or drive signal is applied to SAW transducer 620. In response, transducer 620 excites an acoustic wave (not shown) in piezoelectric layer 620. In device 600 without optional ground plate 602, this acoustic wave is likely to be the so-called Raleigh mode wave with particle motion occurring in the sagittal plane along the top surface of layer 620. The peak amplitudes of Raleigh-mode (and the peak amplitudes of the corresponding piezoelectrically-coupled electric field waves) are near the top surface of layer 620. The wave amplitudes decrease with depth below the top surface and are insignificant at depths of about an acoustic wavelength. In a device 600 having optional AC ground plane 602 as shown in FIG. 38, the acoustic wave excited by transducer 620 is likely to be a relatively faster higher-order acoustic mode wave, for example, the so-called Sezawa mode wave. Sezawa-mode waves preferentially propagate along the bottom surface of layer 620 (i.e., along the interface between layer 620 and substrate 601). The peak amplitudes of Sezawa-mode acoustic waves and corresponding piezoelectrically-coupled electric field waves are also near the bottom surface of layer 610 closer to semiconductor substrate 601. Sezawa-mode acoustic waves generally develop stronger piezoelectrically coupled electric field amplitudes in silicon substrate 601 than Raleigh-mode waves do for the same clock signal power applied to transducer 620. Optional ground plates 602, which help generate Sezawa-mode excitations may, therefore, be desirable for higher device efficiency.

In either case of Raleigh-or Sezawa-mode acoustic wave excitations, a bias voltage Vg may be applied to gate electrode 622 to electrostatically displace the potential associated with the piezoelectrically-coupled electric field waves by a DC (constant) value to properly form the potential wells in the silicon substrate 601. Applied bias voltage Vg may be sufficiently positive so that the electric field in silicon is positive for all phases of the traveling acoustic/electrical field wave. The displaced potential field is figuratively represented in FIG. 38 by generally sinusoidal line 660. Sinusoidal line 660 is shown as beginning from a rectangular potential well 661 underneath input diode 603 and terminating in a rectangular potential well 662 underneath output diode 604. It will be understood that the displaced potential quantum wells 660 are not stationary but travel from left to right with the same speed as the excited acoustic wave. Shaded regions 651, 652, and 653, schematically represent the electronic charge level underneath input diode 603 corresponding to input voltage Vin at input diode 603, charge packets that are trapped and are transported in potential quantum wells 660, and the electronic charge transferred to output diode 604, respectively.

In one embodiment, device 600 as configured in FIG. 38 may function as a sampled-signal delay line. Input signal Vin applied to input diode 602 injects charge into potential well 661. The amount of injected charge is proportional to Vin. The injected charge is picked up (or sampled) by the traveling potential quantum wells 660 at a sampling frequency equal to the frequency of the acoustic wave (which is the same as the clock signal frequency applied to transducer 620). This charge is trapped in potential quantum wells 660 (e.g., as charge packet 652) and is transported to potential well 662 by traveling potential quantum wells 660. Output signal Vout is proportional to the charge level in region 653.

Output signal Vout responds proportionally to changes in charge level 653 due to the arrival of transported charge packets 652 at potential well 662. The time delay in the arrival of transported charge packet 652 at potential well 662 after being picked up at potential well 661 is equal to the time it takes for the excited acoustic wave to travel the same distance. Since acoustic waves travel at substantially slower speeds than the speed of electrical signals, device 600 can be used in signal processing circuitry as a delay-line with large values of delay time.

Other embodiments of ACT devices in accordance with the invention may be configured to provide other signal processing functions. For example, FIG. 39 illustrates ACT device 700 configured for use as a programmable delay line, a finite impulse response (FIR) filter with programmable weighting factors, or an infinite impulse response (IIR) filter also with programmable weighting factors in conjunction with other programming circuitry 792.

As a first alternative, device 700 and programming circuitry 792 may be fabricated on separate device structures for use as interconnected hybrids. For example, device 700 may be fabricated as a discrete device on monolithic structures such as structure 6000 (FIG. 31) while programming circuitry 792 is fabricated on conventional silicon wafers. As a second alternative, device 700 and programming circuitry 792 may be integrated on a single monolithic structure in accordance with previously described embodiments of the invention. For example, device 700 may be fabricated on piezoelectric region 404 of monolithic structure 400 while integrated programming circuitry 792 is fabricated on semiconductor region 403 of same monolithic structure 400 (FIG. 34). The following description of device 700 and programming circuitry 792 is applicable to both these alternatives.

Device 700 has semiconductor elements formed on p-doped silicon substrate 601 and has piezoelectric elements formed on piezoelectric layer 610. Intermediate amorphous layer 612 serves to accommodate any strain caused by lattice mismatch between substrate 601 and layer 610.

The piezoelectric elements of device 700 include transducer 620 and gate electrode 622. A clock signal (not shown) applied to transducer 620 excites an acoustic wave, which is accompanied by a piezoelectrically-coupled electric field wave (not shown). By implementing a suitable design of transducer 620, use of optional acoustic absorbers 626 and 628, and other conventional techniques mentioned earlier, the excited acoustic wave may be conditioned to travel from left to right in direction 790. A bias voltage Vg applied to gate electrode 622 electrostatically displaces potential wells corresponding to the piezoelectrically-coupled electric field wave by a DC (constant) value to properly form the potential wells in the semiconductor substrate 601. The displaced potential field is figuratively depicted in FIG. 39 by generally sinusoidal line 750.

The semiconductor elements of device 700 include optional AC ground plate 602, input diode 603, and any suitable number of non-disturbing filter signal taps. The number of filter signal taps and the corresponding packet arrival delays determine the resolution of the frequency response of device 700. This number may be as large as can be practically fit in a device structure of a given length. Device lengths may, for example, be of the order of a few tens of microns to a few hundred microns. For purposes of illustration, device 700 as shown in FIG. 39 is configured with four signal taps 751, 752, 753, and 754. Signal taps 751-754 are laterally spaced apart from each other and are at some distance from input diode 603 in direction 790. Signal taps 751-754 may, for example, be N+ doped buried lines orthogonal to the direction 790. Signal taps 751-754 are electrically connected to programming circuitry 792 by metallic conductors figuratively depicted by lines 755 in FIG. 38.

In the operation of device 700, at about time t=0, input signal Vin applied to input diode 602 injects an amount of electronic charge proportional to Vin into potential well 661. Traveling potential wells 750 pick up this injected charge, for example, as a charge packet 652. The amount of charge in charge packet 652 is proportional to the injected charge and, hence, is also proportional to input signal Vin sampled at about time t=0. Charge packet 652 is transported by potential wells 750 toward signal taps 751-754 at a speed corresponding to the speed of the excited acoustic wave. Charge packet 652 passes across signal taps 751, 752, 753, and 754 at sequentially increasing delay times t=t1, t=t2, t=t3, and t=t4, respectively. Times t1, t2, t3, and t4 correspond to the time it takes for the excited acoustic wave to traverse the distance from input diode 622 to signal taps 751, 752, 753, and 754, respectively.

Signal taps 751-754 sense the amount of charge in charge packets 652. The taps, in conjunction with interconnect 755 and high impedance amplifiers 793, are designed to generally sense the amount of charge without disturbing or significantly altering charge packet 652. Signal taps 751-754 generate output sense signals proportional to the amount of charge in charge packet 652 traveling underneath them. The sense signals generated by signal taps 751-754 at a time t are proportional to input signal Vin at earlier times −t1, −t2, −t3 and −t4, respectively. These output sense signals are transmitted to amplifier/programmable combining circuitry 792 over electrical connections 755. Charge packets 652 traveling past signal taps 751-754 dissipate in the bulk of device 700 and are collected by suitable ground terminals, for example, through grounding diode 770.

The sense signal from each of taps 751-754 transmitted to programming circuitry 792 is coupled through a high impedance amplifier 793 whose output voltage is proportional to input charge, to a variable gain amplifier 794. The high impedance amplifiers 793 are designed so that they do not remove significant charge information from signal taps 751-754. This allows signal taps 751-754 to sense charge packets 652 without depleting or disturbing charge packets 652. High impedance amplifier 793 may, for example, be high impedance FET based amplifiers. Variable gain amplifiers 794 have variable gain G that may be set or programmed to have an arbitrary normalized value between −1 and 1. Sense signals amplified by amplifiers 794 are added together in summing circuit 795. The output summing circuit 795 may represent the processed output of device 700 for some functional uses of device 700 as described below. Variable gain amplifiers 794 and summing circuit 795 may be any suitable conventional semiconductor device circuits.

Programming circuitry 792 may optionally include a feedback circuit (not shown) for providing feedback signals to input diode 603. The feedback circuit may include another set of variable gain amplifiers similar to variable gain amplifiers 794 but whose outputs are fed back to input diode 603. A portion of the output sense signals generated by taps 751-754 may be diverted to the variable gain amplifiers in the feedback circuit to generate feedback signals for feed back to input diode 603. Device 700 operates as a time delay line for the fed back signals. Sense signals fed back to input diode 603 at time t=0 reappear at taps 751-754 after a time delay of t1, t2, t3 and t4, respectively.

As mentioned earlier, device 700 in conjunction with programming circuit 792 may be programmed to function as a variable delay line with a selectable time delay value. The time delay value for device 700 as configured in FIG. 38 may be chosen from the set of four delay times t1, t2, t3, and t4. A particular value may be chosen by setting the gain of variable amplifier 793 coupled to the signal tap associated with that time delay value equal to unity and by setting the gain of other variable amplifiers 794 equal to zero. For example, to select a time delay value of t3, the gain of variable amplifier 793 coupled to signal tap 753 is set to 1, and the gain of other variable amplifiers 793 coupled to signal taps, 751, 752, and 754 are set to zero.

Optionally, device 700 may be programmed to function as a FIR filter with programmable weighting factors. The functioning of device 700 as a FIR filter in conjunction with programming circuitry 792 may be understood by recognizing that a FIR filter produces an output which is proportional to a weighted linear sum of past or earlier inputs. As described above, the sense signals generated by taps 751-754 are proportional to input signal Vin at earlier times, t−t1, t−t2, t−t3 and t−t4, respectively. Summing circuit 795 produces an output 796, which is a sum of these sense signals weighted by the gains G of amplifiers 794. Thus, providing programming circuit 792 with variable gain amplifiers 793 whose gain is programmable allows device 700 to function as a FIR filter with programmable weighting factors.

The optional functioning of device 700 in a signal processing circuit as an IIR filter requires use of the optional feedback circuitry which is not shown in FIG. 38 but has been described earlier. The functioning of device 700 as an IIR filter may be understood by recognizing that an IIR filter produces an output which, by virtue of having feedback, depends on all previous signal inputs since an initialization of device 700. With device 700 operating in feedback mode, sense signals generated by signal taps 751-754 include contributions proportional to these past outputs in addition to contributions proportional to past input signals Vin. Therefore, the weighting and summing of the sense signals by programming circuit 792 produces an output 796 which is a weighted sum of both past input and past outputs, i.e. an IIR filter output.

The ACT devices configured according to the invention, for example, device 700 described above, may be expected to have superior frequency response characteristics compared to traditional SAW device based FIR and IIR filters. In traditional SAW devices, electrical input signals are piezoelectrically converted into an acoustic wave signal which is then reconverted into an output electrical signal by input and output transducers, respectively. However, because of physical effects such as boundary effects and finite size effects only acoustic waves having frequencies in a limited range can be guided by the piezoelectric layer from input to output without significant attenuation. In particular, the interdigitated transducer means of conversion of electrical signals into acoustic signals is fundamentally limited to a narrow range of frequencies. Therefore, traditional SAW devices using such means do not respond to low frequency input signals. Filters based on these traditional SAW devices can at most have a pass band frequency response.

In contrast, the ACT devices of the present invention are base band devices which respond to input signals over a bandwidth which extends down to zero frequency (i.e., to a DC signal). It will be appreciated that in the ACT devices of the present invention, (e.g., devices 600 and 700 above) no conversion in physical form of input electrical signals to acoustic waves is involved. The acoustic waves in ACT devices are generated by a fixed frequency clock signal that is independent of the electrical signals being transmitted through the device. These acoustic waves are used only as a mechanism to sample the electrical signals being transmitted through the device. The sampling frequency (i.e., the clock signal frequency) determines an upper band limit of the frequency response of the ACT devices. By the well-known Nyquist theorem from sampling theory, this upper band limit is known to be equal to one half the clock signal frequency.

Thus, monolithic device structures that include semiconductor material and piezoelectric material suitable for making and integrating electro-acoustic devices with semiconductor devices are provided. Acoustic charge transport devices, which may be formed using semiconductor-piezoelectric monolithic devices, are also provided.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

As used herein, the terms “comprises,” “comprising,” or any other variation thereof, are intended to cover a non-exclusive inclusion, such that a process, method, article, or apparatus that comprises a list of elements includes not only those elements but may also include other elements not expressly listed or inherent to such process, method, article, or apparatus. Further as used herein, terms such as “strain,” and “stress,” are intended to cover each other where appropriate. One skilled in the art will appreciate that the present invention can be practiced by other than the described embodiments, which are presented for purposes of illustration and not of limitation, and the present invention is limited only by the claims which follow.

1. A monolithic semiconductor-piezoelectric structure comprising:
a substrate of a first monocrystalline semiconductor material;
at least one strain-relief material layer, each said at least one strain-relief material layer overlying a respective portion of said monocrystalline semiconductor substrate;
at least one portion of a piezoelectric material, each said portion overlying a respective one of said at least one strain-relief material layer; and
an electro-acoustic device at least partially in at least one said portion of piezoelectric material.

2. The semiconductor-piezoelectric structure of claim 1 wherein said semiconductor material is silicon.

3. The semiconductor-piezoelectric structure of claim 1 wherein said piezoelectric material is a metallic oxide.

4. The semiconductor-piezoelectric structure of claim 1 wherein said piezoelectric material is lithium niobate.

5. The semiconductor-piezoelectric structure of claim 1 wherein said piezoelectric material is lithium tantalate.

6. The semiconductor-piezoelectric structure of claim 1 wherein said strain-relief material is Sr_{z}Ba_{1-z}TiO₃, where z has a value chosen between 0 and 1.

7. The semiconductor-piezoelectric structure of claim 1 wherein said strain-relief material comprises an amorphous material.

8. The semiconductor-piezoelectric structure of claim 1 wherein said strain-relief material comprises a crystalline material.

9. The semiconductor-piezoelectric structure of claim 1 wherein said strain-relief material comprises an oxide of silicon.

10. The semiconductor-piezoelectric structure of claim 1 wherein said electro-acoustic device is a passive surface acoustic wave device.

11. The semiconductor-piezoelectric structure of claim 1 wherein said electro-acoustic device is an active device.

12. The semiconductor-piezoelectric structure of claim 11 wherein said active device comprises an acoustic charge transport device.

13. The device of claim 12 wherein a substantial portion of charge transfer through said acoustic charge transport device is through a semiconductor substrate region proximate to said piezoelectric layer.

14. The device of claim 12 wherein traveling potential wells transport charge in said device, and wherein said potential wells are piezoelectrically coupled to an acoustic wave transduced in said piezoelectric layer.

15. The monolithic semiconductor-piezoelectric structure of claim 1, further comprising:
at least one semiconductor device formed in a semiconductor portion of said substrate; and
at least one electrical connection between one of said semiconductor devices and said electro-acoustic device.

16. A method for integrating an electro-acoustic device with a semiconductor device in a circuit, said method comprising:
providing a monolithic structure that comprises:
a substrate of a first monocrystalline semiconductor material;
at least one strain-relief material layer, each said at least one strain-relief material layer overlying a respective portion of said monocrystalline semiconductor substrate;
at least one portion of a piezoelectric material, each said portion overlying a respective one of said at least one strain-relief material layer,
forming an electro-acoustic device at least partially in at least one said portion of piezoelectric material;
forming a semiconductor device at least partially in a semiconductor region in said substrate; and
providing an electrical connection between said semiconductor device and said electro-acoustic device.

17. The method of claim 16 wherein said first monocrystalline semiconductor material is semiconductor silicon.

18. The method of claim 16 wherein said piezoelectric material comprises a metallic oxide.

19. The method of claim 16 wherein said piezoelectric material is lithium niobate.

20. The method of claim 16 wherein said piezoelectric material is lithium tantalate.

21. The method of claim 16 wherein said strain-relief material comprises Sr_{z}Ba_{1-z}TiO₃, where z has a value chosen between 0 and 1.

22. The method of claim 16 wherein said strain-relief material comprises a crystalline material.

23. The method of claim 16 wherein said strain-relief material comprises an amorphous material formed by amorphizing a crystalline material by heat treatment during fabrication of said monolithic structure.

24. The method of claim 16 wherein said strain-relief material comprises an oxide of silicon.

25. The method of claim 16 wherein said electro-acoustic device comprises a passive surface acoustic wave device.

26. The method of claim 16 wherein said electro-acoustic device comprises an active device.

27. The method of claim 26 wherein said active device comprises an acoustic charge transport device.

28. The method of claim 27 wherein a substantial portion of charge transfer in said acoustic charge transport device is through a semiconductor substrate region proximate to said piezoelectric layer.

29. The device of claim 26 wherein said charge transport is by way of traveling potential wells, and wherein said potential wells are piezoelectrically coupled to an acoustic wave transduced in said piezoelectric layer.

30. A method for forming a semiconductor-piezoelectric monolithic structure having an electro-acoustic device, comprising:
preparing a surface on a first monocrystalline semiconductor material substrate for epitaxial growth;
preparing a strain-relief layer on at least a portion of said surface; and
epitaxially forming a piezoelectric material layer on said strain-relief layer.

31. The method of claim 30 wherein said first monocrystalline semiconductor material comprises semiconductor silicon.

32. The method of claim 30 wherein said piezoelectric material comprises a metallic oxide.

33. The method of claim 30 wherein said piezoelectric material is lithium niobate.

34. The method of claim 30 wherein said piezoelectric material is lithium tantalate.

35. The method of claim 30 wherein said strain-relief layer comprises Sr_{z}Ba_{1-z}TiO₃, where z has a value chosen between 0 and 1.

36. The method of claim 30 wherein said strain-relief material comprises a crystalline material.

37. The method of claim 30 wherein said strain-relief material comprises an amorphous material.

38. The method of claim 37 wherein said amorphous material is formed by interfacial oxidation of said substrate during said epitaxially forming a piezoelectric material layer.

39. The method of claim 30 wherein said preparing a strain-relief layer and said epitaxially forming a piezoelectric material layer comprise:
forming an initial crystalline strain-relief layer;
forming a thin piezoelectric epitaxial layer on said initial strain-relief layer; and
amorphizing said initial crystalline strain-relief layer.

40. The method of claim 30 further comprising forming said electro-acoustic device at least partially in said piezoelectric material layer.

41. The method of claim 30 wherein said forming said electro-acoustic device comprises forming a passive surface acoustic wave device.

42. The method of claim 30 wherein said forming said electro-acoustic device comprises forming an active device.

43. The method of claim 42 wherein said forming an active device comprises forming an acoustic charge transport device.

44. The method of claim 43 wherein said forming an acoustic charge transport device comprises forming a device wherein a substantial portion of charge transfer is through a semiconductor substrate region proximate to said piezoelectric material layer.

45. The method of claim 43 wherein said forming a device comprises forming said device wherein said charge transport is by way of traveling potential wells, and wherein said potential wells are piezoelectrically-coupled to an acoustic wave transduced in said piezoelectric layer.

46. A monolithic semiconductor-piezoelectric structure comprising:
a substrate of a first monocrystalline semiconductor material;
at least one accommodating layer, each said at least one accommodating layer overlying a respective portion of said monocrystalline semiconductor substrate wherein said accommodating layer is formed of piezoelectric material;
an electro-acoustic device at least partially in at least one said one accommodating layer; and
at least a second monocrystalline semiconductor material, each said at least a second monocrystalline semiconductor material overlying a respective one of said at least one accommodating layer.

47. The semiconductor-piezoelectric structure of claim 46 wherein said first monocrystalline semiconductor comprises a Group IV semiconductor.

48. The semiconductor-piezoelectric structure of claim 46 wherein said piezoelectric material comprises a metallic oxide.

49. The semiconductor-piezoelectric structure of claim 48 wherein said metallic oxide comprises Sr_{z}Ba_{1-z}TiO₃, where z has a value chosen between 0 and 1.

50. The semiconductor-piezoelectric structure of claim 46 wherein said piezoelectric material comprises lithium niobate.

51. The semiconductor-piezoelectric structure of claim 46 wherein said piezoelectric material comprises lithium tantalate.

52. The semiconductor-piezoelectric structure of claim 46 wherein said electro-acoustic device comprises a passive surface acoustic wave device.

53. The semiconductor-piezoelectric structure of claim 46 wherein said electro-acoustic device comprises an active device.

54. The semiconductor-piezoelectric structure of claim 53 wherein said active device comprises an acoustic charge transport device.

55. The device of claim 53 wherein a substantial portion of charge transfer through said acoustic charge transport device is through a semiconductor substrate region proximate to said piezoelectric layer.

56. The device of claim 53 wherein traveling potential wells transport charge in said device, and wherein said potential wells are piezoelectrically coupled to an acoustic wave transduced in said piezoelectric layer.

57. The monolithic semiconductor-piezoelectric structure of claim 46 wherein said second semiconductor comprises a semiconductor selected from the group of Group IV, Group III-V, and Group II-VI-semiconductors.

58. The monolithic semiconductor-piezoelectric structure of claim 46, further comprising:
at least one semiconductor device, and at least one electrical connection between one of said semiconductor devices and said electro-acoustic device.

59. The monolithic semiconductor-piezoelectric structure of claim 58, wherein said at least one semiconductor device is formed at least partially in said substrate.

60. The monolithic semiconductor-piezoelectric structure of claim 58, wherein said at least one semiconductor device is formed at least partially in said second monocrystalline semiconductor material.

61. An electro-acoustic device, comprising
a monocrystalline semiconductor material substrate;
a piezoelectric material layer disposed in proximity to a top surface of said substrate;
a transducer disposed in proximity to a surface of said piezoelectric material layer, said transducer generating an acoustic wave in said piezoelectric material layer in response to a clock signal, said acoustic wave having associated electrical fields;
a gate electrode for applying a bias voltage to electrostatically displace said associated electric fields to form traveling potential wells in said substrate;
an input element for receiving an input signal, said input element injecting charge proportional to said input signal into said substrate, wherein said traveling potential wells periodically sample said injected charge and transport a sample charge packet away from said input element each time said injected charge is sampled; and
at least one output element that senses said amount of charge in said sample charge packet at a later time and generates an output signal proportional to amount of charge in said sample charge packet.

62. An electro-acoustic device defined in claim 61 wherein said monocrystalline semiconductor material substrate comprises a Group IV semiconductor material.

63. An electro-acoustic device defined in claim 61 wherein said piezoelectric material layer comprises a metallic oxide.

64. An electro-acoustic device defined in claim 63 wherein said metallic oxide comprises Sr_{z}Ba_{1-z}TiO₃, where z has a value chosen between 0 and 1.

65. An electro-acoustic device defined in claim 61 wherein said piezoelectric material layer is lithium niobate.

66. An electro-acoustic device defined in claim 61 wherein said piezoelectric material layer is lithium tantalate.

67. The device defined in claim 61 wherein a substantial portion of charge transfer through said device is through a semiconductor substrate region proximate to said piezoelectric layer.

68. An electro-acoustic device defined in claim 61 wherein said input element comprises an input diode.

69. An electro-acoustic device defined in claim 61 wherein at least one of said output element comprises an output diode.

70. An electro-acoustic device defined in claim 61 further comprising an AC ground plane for promoting generation of Sezawa-mode acoustic waves.

71. The electro-acoustic device defined in claim 61 wherein said at least one semiconductor device is formed at least partially in said monocrystalline semiconductor material and wherein said at least one semiconductor device is electrically connected to at least one of said transducer, said gate electrode, said input element and said output element.

72. An electro-acoustic device, comprising
a monocrystalline semiconductor material substrate;
a piezoelectric material layer disposed in proximity to a top surface of said substrate;
a transducer disposed in proximity to a surface of said piezoelectric material layer, said transducer generating an acoustic wave in said piezoelectric material layer in response to a clock signal, said acoustic wave having associated electrical fields
a gate electrode for applying a bias voltage to electrostatically displace said associated electric fields to form traveling potential wells in said substrate;
an input element for receiving an input signal, said input element injecting charge proportional to said input signal into said substrate, wherein said traveling potential wells periodically sample said injected charge and transport a sample charge packet away from said input element each time said injected charge is sampled;
a plurality of laterally-spaced output elements that sense amounts of charge in said sample charge packets travelling across said output elements and generate sense signals proportional to said amounts of charge in said sample charge packets; and
signal processing circuitry fabricated in said monocrystalline semiconductor for receiving and processing said sense signals to generate an output signal.

73. An electro-acoustic device defined in claim 72 wherein said input element comprises an input diode.

74. An electro-acoustic device defined in claim 72 wherein said signal processing circuitry comprises variable gain amplifiers that receive and process said sense signals.

75. An electro-acoustic device defined in claim 72 wherein said signal processing circuitry comprises variable gain amplifiers that receive and process said sense signals.

76. An electro-acoustic device defined in claim 75 wherein said signal processing circuitry further comprises high-impedance elements for coupling said output elements to said variable gain amplifiers.

77. An electro-acoustic device defined in claim 75 wherein said signal processing circuitry further comprises a summing circuit for adding said variable gain amplifiers outputs.

78. An electro-acoustic device defined in claim 75 wherein said signal processing circuitry further comprises a feedback circuit wherein said feedback circuit comprises second variable gain amplifiers that receive and process portions of said sense signals to generate feedback signals that are fed back to said input element.

79. An electro-acoustic device defined in claim 72 wherein said monocrystalline semiconductor material substrate comprises a Group IV semiconductor material.

80. An electro-acoustic device defined in claim 72 wherein said piezoelectric material layer comprises a metallic oxide.

81. An electro-acoustic device defined in claim 80 wherein said metallic oxide comprises Sr_{z}Ba_{1-z}TiO₃, where z has a value chosen between 0 and 1.

82. An electro-acoustic device defined in claim 72 wherein said piezoelectric material layer is lithium niobate.

83. An electro-acoustic device defined in claim 72 wherein said piezoelectric material layer is lithium tantalate.

84. The device of claim 72 wherein said charge transport is by way of traveling potential wells, and wherein said potential wells are piezoelectrically coupled to an acoustic wave transduced in said piezoelectric layer.
